(19) United States
(12) Patent Application Publication
(10) Pub. No.: US 2026/0033006 A1
(43) Pub. Date: Jan. 29, 2026

(54) ARRAY SUBSTRATE, MANUFACTURING METHOD THEREFOR, DISPLAY PANEL AND DISPLAY APPARATUS

(71) Applicant: BOE TECHNOLOGY GROUP CO., LTD., Beijing (CN)

(72) Inventors: Guangcai YUAN, Beijing (CN); Hehe HU, Beijing (CN); Changhan HSIEH, Beijing (CN); Wei YANG, Beijing (CN); Liwen DONG, Beijing (CN); Jiayu HE, Beijing (CN); Dongfei HOU, Beijing (CN); Zhen ZHANG, Beijing (CN); Xin GU, Beijing (CN); Ce NING, Beijing (CN); Zhengliang LI, Beijing (CN)

(73) Assignee: BOE TECHNOLOGY GROUP CO., LTD., Beijing (CN)

(21) Appl. No.: 18/996,920

(22) PCT Filed: Dec. 16, 2022
(86) PCT No.: PCT/CN2022/139736

§ 371 Date: Jan. 17, 2025

(51) Int. Cl. H10D 86/40; G02F 1/1333; G02F 1/1368

(52) U.S. Cl. CPC H10D 86/451; G02F 1/133357; G02F 1/1368

(57) ABSTRACT

An array substrate, a manufacturing method therefor, a display panel and a display apparatus. The array substrate includes a base substrate; a first electrode layer and a first conductive layer successively provided on one side of the base substrate, the first conductive layer includes a source and a drain, a first gap being provided between the source and the drain; an organic planarization layer including a plurality of organic flat parts which are at least arranged inside the first gap, and the included angle between the side wall of an organic flat part close to the first gap and the face of the first conductive layer close to the organic planarization layer being less than the included angle between the side wall of the first conductive layer close to the first gap and the face of the first electrode layer close to the first conductive layer.

CROSS REFERENCE

The present application is a national phase application of International Application No. PCT/CN2022/139736, filed on Dec. 16, 2022, and the entire contents thereof are incorporated herein by reference for all purposes.

### TECHNICAL FIELD

The present disclosure relates to the field of display technology, and in particular to an array substrate and a manufacturing method thereof, a display panel, and a display device.

### BACKGROUND

Flexible display devices are favored by consumers due to their good flexibility, light and thin volume, low power consumption, and rubbing resistance. Flexible OLED (Organic Electroluminescence Display) display devices are already relatively mature, and flexible LCD (Liquid Crystal Display) devices are developing.

It should be noted that, information disclosed in the above background portion is provided only for better understanding of the background of the present disclosure, and thus it may contain information that does not form the prior art known by those ordinary skilled in the art.

### SUMMARY

The present disclosure provides an array substrate and a manufacturing method thereof, a display panel, and a display device.

According to one aspect of the present disclosure, there is provided an array substrate, including:
a base substrate;
a first electrode layer, disposed on a side of the base substrate, the first electrode layer including a first electrode;
a first conductive layer is, disposed on a side of the first electrode layer away from the base substrate, wherein the first conductive layer includes a source electrode and a drain electrode, a first gap is provided between the source electrode and the drain electrode, and an orthographic projection of the drain electrode on the base substrate is overlapped with an orthographic projection of the first electrode layer on the base substrate;
an organic planarization layer, including a plurality of organic planarization portions arranged at intervals, wherein one organic planarization portion is arranged at least in the first gap, at least ends of the source electrode and the drain electrode away from the first gap are not covered by the organic planarization portion, and an angle between a side wall of the organic planarization portion close to the first gap and a surface of the first conductive layer close to the organic planarization layer is smaller than an angle between a side wall of the first conductive layer close to the first gap and a surface of the first electrode layer close to the first conductive layer; and
an organic active layer, disposed on a side of the organic planarization layer away from the base substrate, and the organic active layer is connected to the source electrode and the drain electrode on a side of the organic planarization portion away from the first gap.

In an exemplary embodiment of the present disclosure, a distance between a surface of the organic planarization portion away from the base substrate and the base substrate is greater than or equal to a distance between a surface of the first conductive layer away from the base substrate and the base substrate.

In an exemplary embodiment of the present disclosure, a portion of the organic planarization portion is arranged on the side of the first conductive layer away from the base substrate, and at a position close to the first gap, an orthographic projection of the organic planarization portion on the base substrate is overlapped with an orthographic projection of the source electrode on the base substrate, and the orthographic projection of the organic planarization portion on the base substrate is overlapped with the orthographic projection of the drain electrode on the base substrate.

In an exemplary embodiment of the present disclosure, the angle between the side wall of the organic planarization portion close to the first gap and the surface of the first conductive layer close to the organic planarization layer is less than or equal to 70°.

In an exemplary embodiment of the present disclosure, a distance between a surface of the organic planarization portion away from the base substrate and the first conductive layer is smaller than a thickness of the first conductive layer in a third direction, wherein the third direction is perpendicular to a surface of the base substrate close to the first electrode layer.

In an exemplary embodiment of the present disclosure, a surface of the organic planarization portion away from the base substrate is connected to a side wall of the organic planarization portion via a curved surface.

In an exemplary embodiment of the present disclosure, the first conductive layer further includes a data line connected to the source electrode, and the first electrode layer further includes:
a resistance-reducing connection portion spaced apart from the first electrode, wherein orthographic projections of the source electrode and the data line on the base substrate are located within an orthographic projection of the resistance-reducing connection portion on the base substrate.

In an exemplary embodiment of the present disclosure, the array substrate further includes:
a gate insulating layer group, disposed on a side of the organic active layer away from the base substrate, and an orthographic projection of the gate insulating layer group on the base substrate is coincided with an orthographic projection of the organic active layer on the base substrate; and
a gate layer, disposed on a side of the gate insulating layer group away from the base substrate, wherein the gate layer includes a gate, and an orthographic projection of the gate on the base substrate is coincided with the orthographic projection of the organic active layer on the base substrate.

In an exemplary embodiment of the present disclosure, the gate insulating layer group includes:
a first gate insulating layer, disposed on the side of the organic active layer away from the base substrate; and
a second gate insulating layer, disposed on a side of the first gate insulating layer away from the base substrate, and the second gate insulating layer has a stronger barrier performance to an etching liquid of the gate layer than the first gate insulating layer.

In an exemplary embodiment of the present disclosure, the array substrate further includes:
a passivation layer, disposed on a side of the gate layer away from the base substrate;
a second electrode layer, disposed on a side of the passivation layer away from the base substrate, wherein the second electrode layer includes a second electrode and a gate connecting portion which are arranged at intervals, and the gate connecting portion is connected to two adjacent gates.

In an exemplary embodiment of the present disclosure, the gate layer further includes:
a gate extension portion, connected to at least a side of the gate in a first direction, and the first direction is parallel to a surface of the array substrate close to the first electrode layer.

In an exemplary embodiment of the present disclosure, the array substrate further includes:
a passivation layer, disposed on a side of the gate layer away from the base substrate; and
a second electrode layer, disposed on a side of the passivation layer away from the base substrate, wherein the second electrode layer includes a second electrode and a gate connecting portion which are arranged at intervals, and the gate connecting portion is connected to two adjacent gate extension portions.

In an exemplary embodiment of the present disclosure, the array substrate further includes:
a conductive enhancement layer, disposed on a side of the second electrode layer away from the base substrate, and an orthographic projection of the conductive enhancement layer on the base substrate is located within an orthographic projection of the gate connecting portion on the base substrate.

In an exemplary embodiment of the present disclosure, the array substrate further includes:
a light shielding layer, disposed on a side of the base substrate, and the orthographic projection of the organic active layer on the base substrate is located within an orthographic projection of the light shielding layer on the base substrate;
a second planarization layer, disposed on a side of the light shielding layer away from the base substrate, wherein the first electrode layer is disposed on a side of the second planarization layer away from the base substrate, and a third via hole is disposed on the second planarization layer;
a passivation layer, disposed on a side of the gate layer away from the base substrate, and a first via hole and a second via hole are provided on the passivation layer, wherein the first via hole is connected to the gate, and the second via hole is connected to the third via hole and connected to the light shielding layer; and
a second electrode layer, disposed on a side of the passivation layer away from the base substrate, wherein the second electrode layer includes a second electrode and a gate connecting portion arranged at intervals, the gate connecting portion is connected to the gate through the first via hole, and is connected to the shading layer through the second via hole and the third via hole, and the shading layer is multiplexed as a gate line and a second gate.

In an exemplary embodiment of the present disclosure, the array substrate further includes:
a protective layer, at least a side wall of the organic active layer is covered by the protective layer.

In an exemplary embodiment of the present disclosure, the protective layer is disposed between the gate layer and the passivation layer, and between the first electrode and the passivation layer, and side walls of the organic active layer, the gate insulating layer group and the gate are covered by the protective layer, and wherein a compatibility of the protective layer with the organic active layer is stronger than a compatibility of the passivation layer with the organic active layer.

In an exemplary embodiment of the present disclosure, a work function of the first conductive layer is greater than 4.5 eV.

In an exemplary embodiment of the present disclosure, the array substrate is a flexible array substrate.

According to another aspect of the present disclosure, there is provided a method for manufacturing array substrate, including:
providing a substrate base plate;
forming a first electrode layer and a first conductive layer sequentially stacked on a side of the base substrate, wherein the first electrode layer includes a first electrode, the first conductive layer includes a source electrode and a drain electrode, a first gap is provided between the source electrode and the drain electrode, and an orthographic projection of the drain electrode on the base substrate is overlapped with an orthographic projection of the first electrode layer on the base substrate;
forming an organic planarization layer, wherein the organic planarization layer includes a plurality of organic planarization portions arranged at intervals, and one organic planarization portion is arranged at least in the first gap; and
forming an organic active layer on a side of the organic planarization layer away from the base substrate, wherein the organic active layer is connected to the source electrode and the drain electrode on a side of the organic planarization portion away from the first gap;
wherein at least ends of the source electrode and the drain electrode away from the first gap are not covered by the organic planarization portion, and an angle between a side wall of the organic planarization portion close to the first gap and a surface of the first conductive layer close to the organic planarization layer is smaller than an angle between a side wall of the first conductive layer close to the first gap and a surface of the first electrode layer close to the first conductive layer.

In an exemplary embodiment of the present disclosure, a gate insulating layer group and a gate electrode layer are formed simultaneously with forming the organic active layer on the side of the organic planarization layer away from the base substrate.

In an exemplary embodiment of the present disclosure, forming the gate insulating layer group and the gate layer simultaneously with forming the organic active layer on the side of the organic planarization layer away from the base substrate, includes:
sequentially forming an organic active material layer, a gate insulating material layer group and a gate material layer on the side of the organic planarization layer away from the base substrate;
performing patterning on the gate material layer to form the gate layer; and
performing patterning on the gate insulating material layer group and the organic active material layer by using the gate layer as a mask to form the gate insulating layer group and the organic active layer.

In an exemplary embodiment of the present disclosure, forming the first electrode layer and the first conductive layer stacked in sequence on the side of the base substrate, includes:
forming a first electrode material layer and a first conductive material layer sequentially on the side of the base substrate,
forming a mask layer on a side of the first conductive material layer away from the base substrate, and performing a halftone mask process on the mask layer to form a mask pattern, wherein the mask pattern includes a first portion and a second portion, the first portion is thicker than the second portion, the first portion is aligned to the first conductive layer and a portion of the first electrode layer, and the second portion is aligned to another portion of the first electrode layer;
etching and removing an exposed part of the first conductive material layer, and etching and removing the first electrode material layer to form the first electrode layer;
performing an ashing process on the mask pattern to remove the second portion, to expose the first conductive material layer covered by the second portion; and
patterning remaining first conductive material layer to form the first conductive layer.

In an exemplary embodiment of the present disclosure, the method further includes:
forming a passivation layer on a side of the gate layer away from the base substrate, and patterning the passivation layer to form a first via hole.

In an exemplary embodiment of the present disclosure, the method further includes:
forming a protective layer and a passivation layer sequentially on a side of the gate layer away from the base substrate, patterning the passivation layer to form a first via hole, and simultaneously patterning the protective layer to form a fourth via hole.

In an exemplary embodiment of the present disclosure, the method further includes:
forming a protective layer and a passivation layer sequentially on the side of the gate layer away from the base substrate, patterning the passivation layer to form a first via and a second via, simultaneously patterning the protective layer to form a fourth via and a fifth via, and simultaneously patterning the second planarization layer to form a third via, wherein the fourth via is connected to the first via, and the fifth via is connected to the second via and the third via.

In an exemplary embodiment of the present disclosure, the method further includes:
forming a second electrode material layer on a side of the passivation layer away from the base substrate, and patterning the second electrode material layer to form a second electrode layer.

In an exemplary embodiment of the present disclosure, the manufacturing method further includes:
forming a second electrode material layer and a conductive enhancement material layer sequentially on a side of the passivation layer away from the base substrate, and patterning the conductive enhancement material layer and the second electrode material layer to form a conductive enhancement layer and a second electrode layer.

According to another aspect of the present disclosure, there is provided a display panel, including:
an array substrate, which is any one of the above array substrates;
a color filter substrate, disposed opposite to the array substrate; and
a liquid crystal layer, disposed between the array substrate and the color filter substrate.

In an exemplary embodiment of the present disclosure, the array substrate is a flexible array substrate, and the color filter substrate is a flexible color filter substrate.

According to another aspect of the present disclosure, there is provided a display device, including: any one of the above the display panel, wherein the display device is a roll-up display device, a foldable display device or a curved display device.

It is to be understood that both the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for ordinary technicians in this field, other accompanying drawings can be obtained based on these accompanying drawings without creative effort.

FIG. 1 is a schematic structural diagram of a first exemplary embodiment of an array substrate disclosed in the present disclosure.

FIG. 2 is a schematic structural diagram of a light shielding layer in FIG. 1.

FIG. 3 is a schematic structural diagram after a first electrode layer and a first conductive layer are formed on the basis of FIG. 2.

FIG. 4 is a schematic diagram of a structure after an organic planarization layer is formed on the basis of FIG. 3.

FIG. 5 is a schematic structural diagram of the structure after an organic active layer, a gate insulating layer group and a gate layer are formed on the basis of FIG. 4.

FIG. 6 is a schematic structural diagram of the organic active layer, the gate insulating layer group and the gate layer in FIG. 5.

FIG. 7 is a schematic structural diagram after a second electrode layer is formed on the basis of FIG. 5.

FIG. 8 is a schematic structural diagram of the second electrode layer in FIG. 7.

FIG. 9 is a schematic cross-sectional view taken along line B-B in FIG. 7.

FIG. 10 is a schematic structural diagram of a second exemplary embodiment of an array substrate disclosed herein.

FIG. 11 is a schematic structural diagram of a third exemplary embodiment of an array substrate disclosed in the present invention.

FIG. 12 is a schematic structural diagram of another exemplary embodiment after an organic active layer, a gate insulating layer group and a gate layer are formed on the basis of FIG. 4.

FIG. 13 is a schematic structural diagram of the organic active layer, the gate insulating layer group and the gate layer in FIG. 12.

FIG. 14 is a schematic diagram of the structure after a second electrode layer is formed on the basis of FIG. 12.

FIG. 15 is a schematic structural diagram of the second electrode layer in FIG. 14.

FIG. 16 is a schematic structural diagram of a fourth exemplary embodiment of an array substrate disclosed in the present invention cut along the line B-B in FIG. 7 or FIG. 14.

FIG. 17 is a schematic structural diagram of a fourth exemplary embodiment of an array substrate disclosed herein cut along the line A-A in FIG. 7 or 14.

FIG. 18 is a schematic structural diagram of a fifth exemplary embodiment of an array substrate disclosed herein taken along the line A-A in FIG. 7 or FIG. 14.

FIG. 19 is a schematic structural diagram of the fifth exemplary embodiment of the array substrate disclosed in the present invention cut along the line B-B in FIG. 7 or 14.

FIG. 20 is a schematic structural diagram of a sixth exemplary embodiment of an array substrate according to the present disclosure.

FIG. 21 is a schematic flow chart of an exemplary embodiment of a method for manufacturing an array substrate according to the present invention.

FIG. 22 to FIG. 40 are schematic structural diagrams of the various steps of the method for manufacturing the array substrate disclosed in the present invention.

### DESCRIPTION OF REFERENCE NUMERALS

1. Base substrate; 21. First planarization layer; 22. Second planarization layer; 221. Third via hole;
3. Light shielding layer; 31. Light shielding part;
40. First electrode material layer; 4. First electrode layer; 41. First electrode; 42. Resistance reducing connection portion; 43. Second gap;
50. First conductive material layer; 5. First conductive layer; 51. Source electrode; 52. Drain electrode; 53. Data line; 54. First gap;
6. Organic planarization layer; 61. Organic planarization portion;
70. Organic active material layer; 7. Organic active layer;
8. Gate insulating layer group; 810. First gate insulating material layer; 81. First gate insulating layer; 820. Second gate insulating material layer; 82. Second gate insulating layer;
90. Gate material layer; 9. Gate layer; 91. Gate; 92. Gate extension portion;
10. Passivation layer; 101. First via hole; 102. Second via hole;
11. Second electrode layer; 111. Second electrode; 112. Gate connecting portion;
12. Adhesive layer; 13. Glass substrate; 14. Protective layer; 141. Fourth via hole;
15. Conductive reinforcement layer;
16. Mask pattern; 161. First portion; 162. Second portion; 17. Second mask pattern;
X. First direction; Y. Second direction; Z. Third direction.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of their objects.

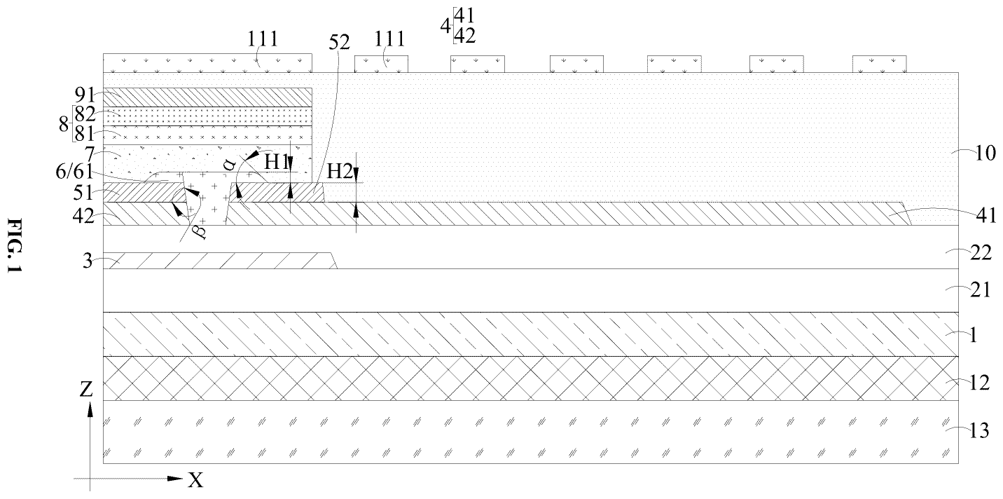

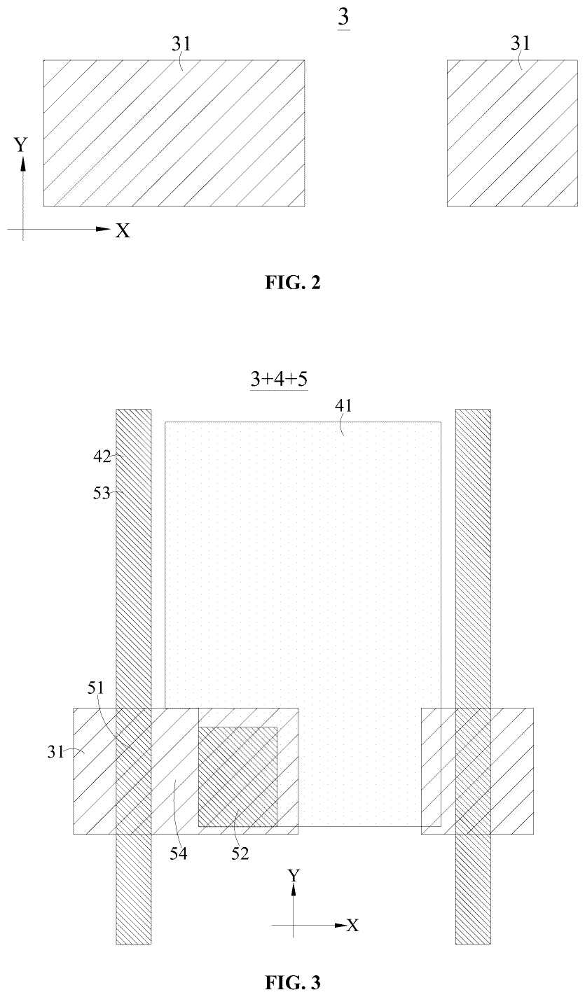

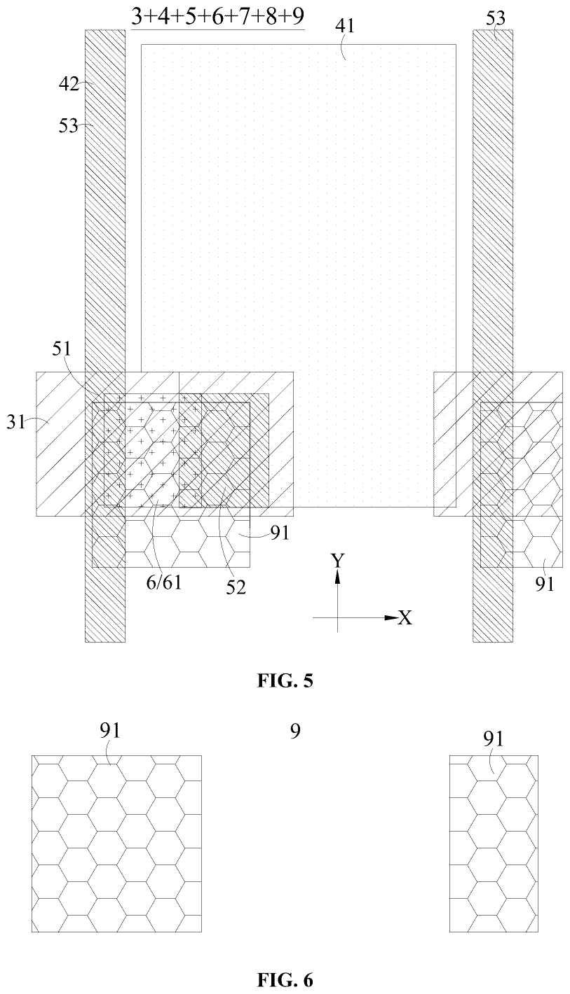

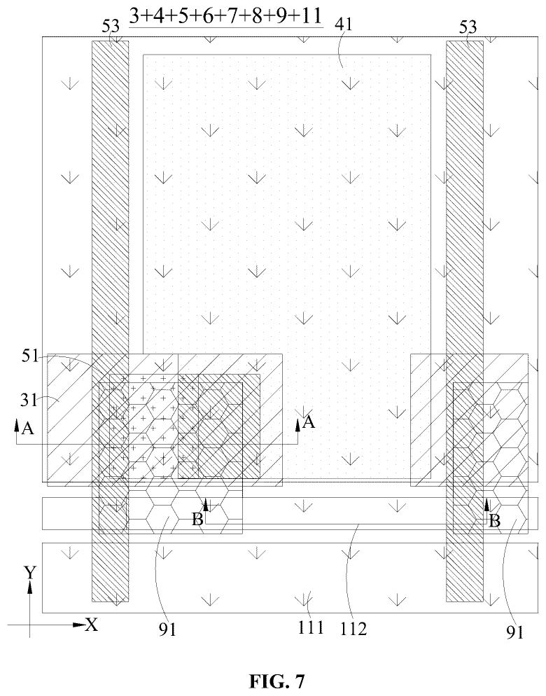

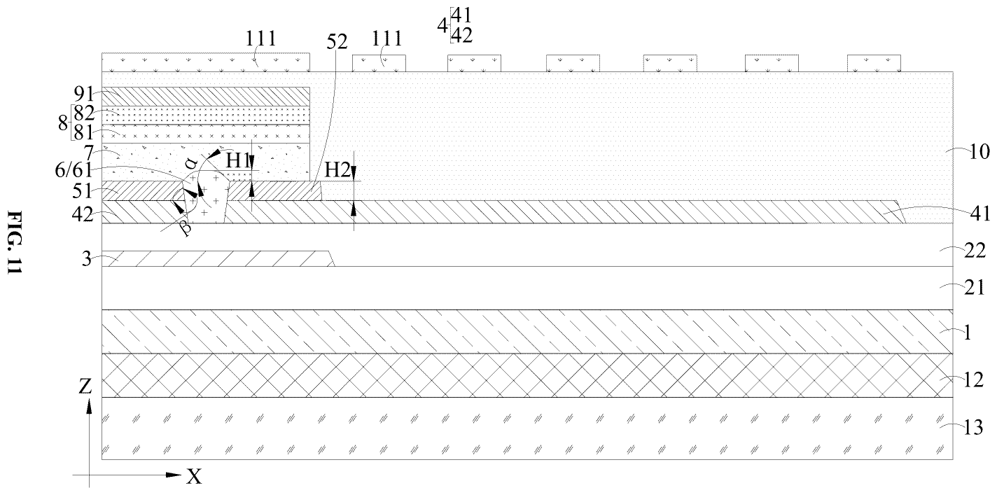

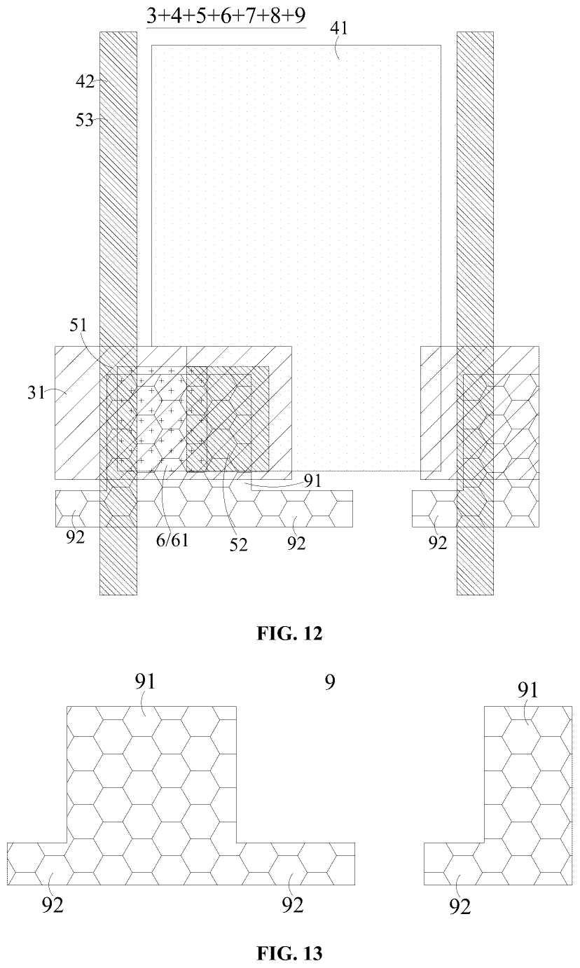

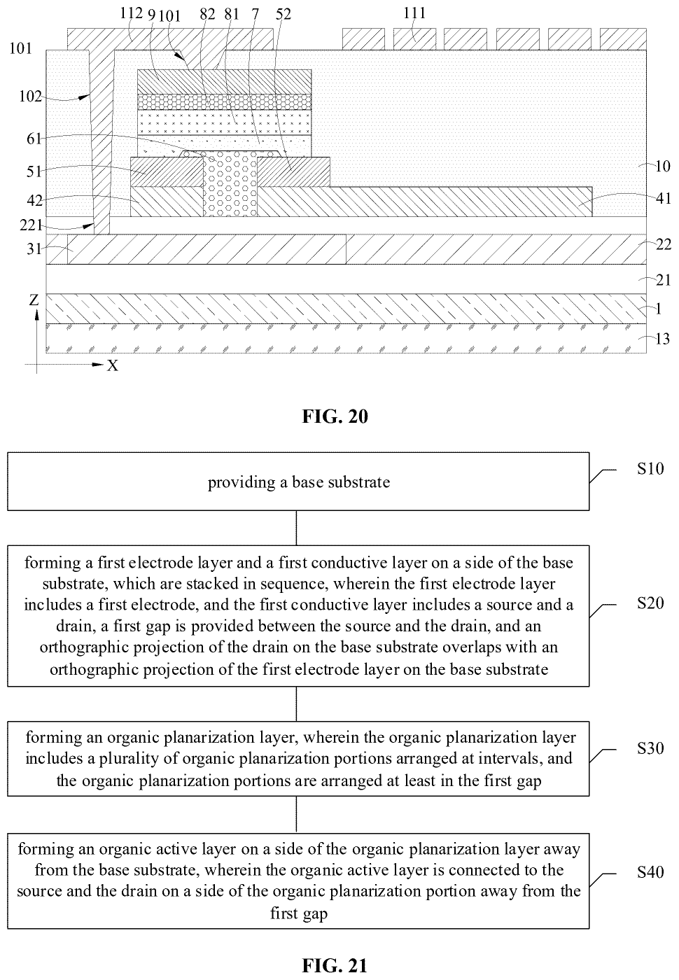

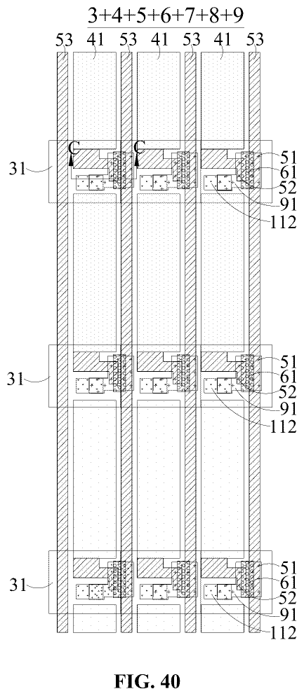

The exemplary embodiment of the present disclosure provides an array substrate, as shown in FIGS. 1-20 and 22-40, where FIG. 1 is a cross-sectional schematic diagram after cutting along AA in FIG. 7; since the organic active layer 7, the gate insulating layer group 8 and the gate layer 9 are formed by the same patterning process, only the gate layer 9 at the top is shown in FIG. 5, FIG. 12 and FIG. 37. In order to show the connection relationship of the gate, only the specific structure of a complete sub-pixel and the data line of another adjacent sub-pixel, part of the gate and part of the light shielding layer are shown in FIGS. 2-8 and FIGS. 12-15. FIG. 20 is a cross-sectional schematic diagram after cutting along C-C in FIG. 40. In FIG. 40, in order to avoid the second electrode 111 from blocking the lower layer, the second electrode 111 is omitted and only the gate connecting portion 112 is drawn.

The array substrate may include a base substrate 1, a first electrode layer 4, a first conductive layer 5, an organic planarization layer 6, and an organic active layer 7; the first electrode layer 4 is arranged on a side of the base substrate 1, and the first electrode layer 4 includes a first electrode 41; the first conductive layer 5 is arranged on the side of the first electrode layer 4 away from the base substrate 1, and the first conductive layer 5 includes a source electrode 51 and a drain electrode 52, a first gap 54 is arranged between the source electrode 51 and the drain electrode 52, and the orthographic projection of the drain electrode 52 on the base substrate 1 is overlapped with the orthographic projection of the first electrode layer 4 on the base substrate 1; the organic planarization layer 6 may include a plurality of organic planarization portions 61 arranged at intervals, and the organic planarization portion 61 is at least arranged in the first gap 54, and the organic planarization portion 61 at least does not cover the ends of the source electrode 51 and the drain electrode 52 away from the first gap 54, and the angle between the side wall of the organic planarization portion 61 close to the first gap 54 and the surface of the first conductive layer 5 close to the organic planarization layer 6 is smaller than the angle between the side wall of the first conductive layer 5 close to the first gap 54 and the surface of the first electrode layer 4 close to the first conductive layer 5; the organic active layer 7 is arranged on the side of the organic planarization layer 6 away from the base substrate 1, and the organic active layer 7 is connected to the source electrode 51 and the drain electrode 52 on the side of the organic planarization portion 61 away from the first gap 54.

In the array substrate disclosed in the present invention, on one hand, the angle between the side wall of the organic planarization layer 6 close to the first gap 54 and the surface of the first conductive layer 5 close to the organic planarization layer 6 is smaller than the angle between the side wall of the first conductive layer 5 close to the first gap 54 and the surface of the first electrode layer 4 close to the first conductive layer 5, and no gap will be formed at the organic active layer 7 on the side wall of the organic planarization layer 6, and the organic active layer 7 will not be broken due to the gap. On the other hand, the organic planarization portion 61 is at least arranged in the first gap 54, and the distance between the surface of the organic planarization portion 61 away from the base substrate 1 and the base substrate 1 is greater than or equal to the distance between the surface of the first conductive layer 5 away from the base substrate 1 and the base substrate 1, so that the organic planarization portion 61 can block the corner of the source 51 and the drain 52 close to the first gap 54, and avoid the sharp corner formed by the corner of the source 51 and the drain 52 close to the first gap 54 so that the organic active layer 7 cannot cover it, that is, the organic active layer 7 can well cover the organic planarization portion 61 and the first conductive layer 5, and achieve a better conductive effect. On the other hand, the array substrate uses an organic active layer 7 and an organic planarization layer 6, and the overall process temperature is less than 100° C., so that the array substrate has sufficient flexibility and can be used in a flexible display panel.

In this example embodiment, the array substrate is a flexible array substrate. Therefore, the base substrate 1 is a flexible substrate. The material of the base substrate 1 is a flexible material. Specifically, the material of the base substrate 1 can be a resin material such as triacetate film, polyimide, polycarbonate, polyacrylate, polyetherimide, polyethersulfone, polyethylene terephthalate and polyethylene naphthalate. The base substrate 1 can be formed by multiple layers of material layers. For example, the base substrate 1 can include multiple layers of substrate layers, and the material of the substrate layer can be any of the above materials. Of course, the base substrate 1 can also be formed as a single layer, which can be any of the above materials.

In order to facilitate the preparation and transportation of the array substrate, the base substrate 1 can be adhered to a glass substrate through an adhesive layer 12, and the glass substrate 13 can be peeled off when used. Of course, when the array substrate is used as a rigid base substrate 1, the glass substrate 13 can be retained, and also other rigid substrates can be used instead of the glass substrate 13.

A plurality of thin film transistors arranged in an array may be disposed on a side of the base substrate 1. The thin film transistor may at least include a source electrode 41, a drain electrode 42, an organic active layer 7 and a first gate electrode 91.

As shown in FIG. 1, a first planarization layer 21 may be provided on a side of the base substrate 1. The material of the first planarization layer 21 has strong adhesion, strong corrosion resistance to chemical solvents, good planarization effect, high light transmittance, and low polarity to reduce channel effect and leakage current. The material of the first planarization layer 21 may be epoxy resin photoresist, for example, SU-8 series epoxy resin photoresist. A light shielding layer 3 is provided on the side of the first planarization layer 21 away from the base substrate 1. Light incident from the base substrate 1 side into the organic active layer 7 will generate photogenerated carriers in the organic active layer 7, thereby having a great impact on the characteristics of the thin film transistor, and ultimately affecting the display quality of the display device; the light shielding layer 3 can block the light incident from the base substrate 1 side, thereby avoiding affecting the characteristics of the thin film transistor and avoiding affecting the display quality of the display device. Depending on the type of thin film transistor, the light shielding layer 3 may be omitted.

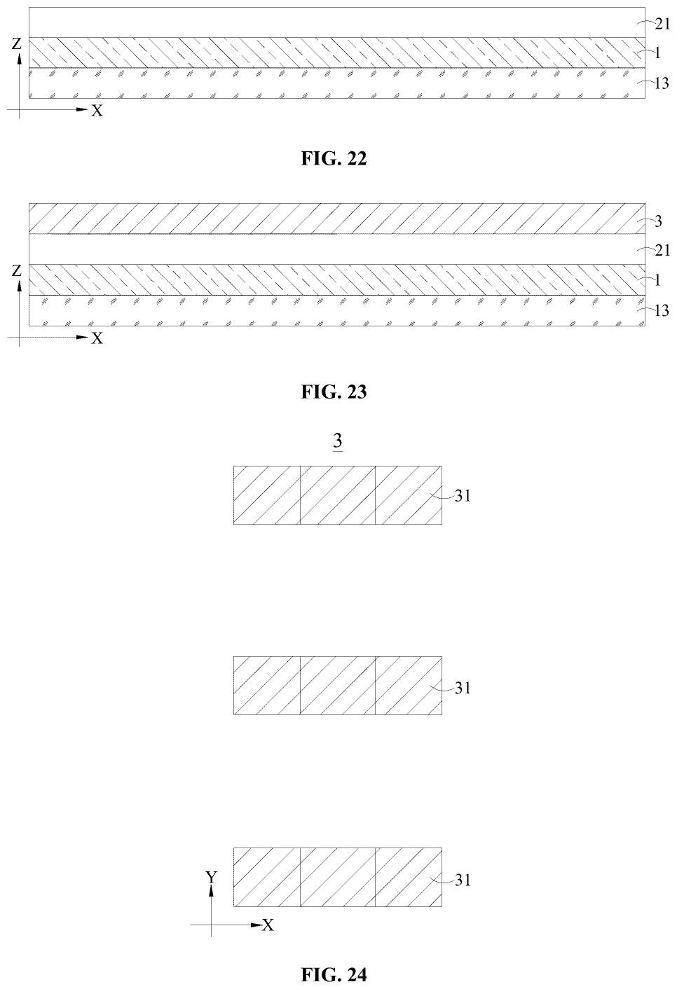

As shown in FIG. 1 and FIG. 2, the light shielding layer 3 may include a plurality of light shielding portions 31 arranged at intervals, and one thin film transistor is correspondingly provided with one light shielding portion 31. Referring to FIG. 22, the light shielding layer 3 may include a plurality of strip-shaped light shielding portions 31 extending along a first direction, and one strip-shaped light shielding portion 31 may correspond to a plurality of thin film transistors arranged along the first direction, that is, the organic active layer 7 of the plurality of thin film transistors arranged along the first direction is shielded by one strip-shaped light shielding portion 31.

A second planarization layer 22 may be provided on the side of the light shielding layer 3 away from the base substrate 1. The material of the second planarization layer 22 is an insulating material. The second planarization layer 22 can insulate and isolate the light shielding layer 3 from the first conductive layer 5. The material of the second planarization layer 22 has strong adhesion, strong corrosion resistance to chemical solvents, good planarization effect, high light transmission, and low polarity to reduce channel effect and leakage current. Specifically, the material of the second planarization layer 22 can be epoxy resin photoresist, for example, SU-8 series epoxy resin photoresist. The thickness of the second planarization layer 22 is greater than or equal to 1 micrometer.

In this example embodiment, as shown in FIG. 1 and FIG. 3, a first electrode layer 4 may be provided on the side of the second planarization layer 22 away from the base substrate 1, and the first electrode layer 4 may include first electrodes 41 and resistance-reducing connecting portions 42 arranged at intervals, and the first electrodes 41 may be pixel electrodes, so that a plurality of first electrodes 41 are arranged at intervals. One sub-pixel is provided with one first electrode 41. The resistance-reducing connecting portion 42 is provided in a strip shape extending along the second direction. The material of the first electrode layer 4 may be a transparent conductive material, for example, ITO (indium tin oxide), IZO (indium zinc oxide), and the like.

In this exemplary embodiment, a first conductive layer 5 may be provided on a side of the first electrode layer 4 away from the base substrate 1, and the first conductive layer 5 may include a data line 53, a source electrode 51, and a drain electrode 52. The data line 53 extends along the second direction Y, and a portion of the data line 53 may be reused as the source electrode 51; or, the data line 53 connects a plurality of source electrodes 51 arranged along the second direction Y, and a data signal may be input to the plurality of source electrodes 51 arranged along the second direction Y through one data line 53. A first gap 54 is provided between the source electrode 51 and the drain electrode 52.

Since the first electrode layer 4 and the first conductive layer 5 are formed by the same patterning process, and the first conductive layer 5 is located above the first electrode layer 4, a first electrode layer 4 is certainly disposed between the first conductive layer 5 and the base substrate 1, that is, the area of the first electrode layer 4 is at least the same as the area of the first conductive layer 5, or the area of the first electrode layer 4 is larger than the area of the first conductive layer 5; specifically, the orthographic projection of the drain 52 on the base substrate 1 overlaps with the orthographic projection of the first electrode layer 4 on the base substrate 1, for example, the orthographic projection of the first electrode layer 4 on the base substrate 1 covers the orthographic projection of the drain 52 on the base substrate 1, and the area of the orthographic projection of the first electrode layer 4 on the base substrate 1 is larger than the area of the orthographic projection of the drain 52 on the base substrate 1. Moreover, the orthographic projections of the source electrode 51 and the data line 53 on the base substrate 1 are located within the orthographic projection of the resistance reduction connection portion 42 on the base substrate 1. For example, the orthographic projection of the resistance reduction connection portion 42 on the base substrate 1 coincides with the orthographic projections of the source electrode 51 and the data line 53 on the base substrate 1; or, the orthographic projection of the resistance reduction connection portion 42 on the base substrate 1 covers the orthographic projections of the source electrode 51 and the data line 53 on the base substrate 1, and the orthographic projection area of the resistance reduction connection portion 42 on the base substrate 1 is larger than the orthographic projection area of the source electrode 51 and the data line 53 on the base substrate 1.

The thickness of the first conductive layer 5 is greater than or equal to 500angstroms and less than or equal to 8000 angstroms. For example, the thickness of the first conductive layer 5 can be 650 angstroms, 982 angstroms, 1020 angstroms, 1190 angstroms, 1380 angstroms, 1850 angstroms, 2340 angstroms, 2840 angstroms, 3240 angstroms, 3840 angstroms, 4180 angstroms, 4586 angstroms, 5170 angstroms, 5760 angstroms, 6230 angstroms, 6840 angstroms, 7520 angstroms, 7850 angstroms, etc.

It should be noted that the so-called “overlap” does not mean complete overlap, but has a certain margin. The tolerance range varies depending on the equipment and preparation process. Therefore, within the tolerance range of the equipment and preparation process, it is considered to be overlap.

The functions of the “source 41” and the “drain 42” may be interchanged when using thin film transistors with opposite polarities or when the current direction changes during circuit operation. Therefore, in this specification, the “source 41” and the “drain 42” may be interchanged.

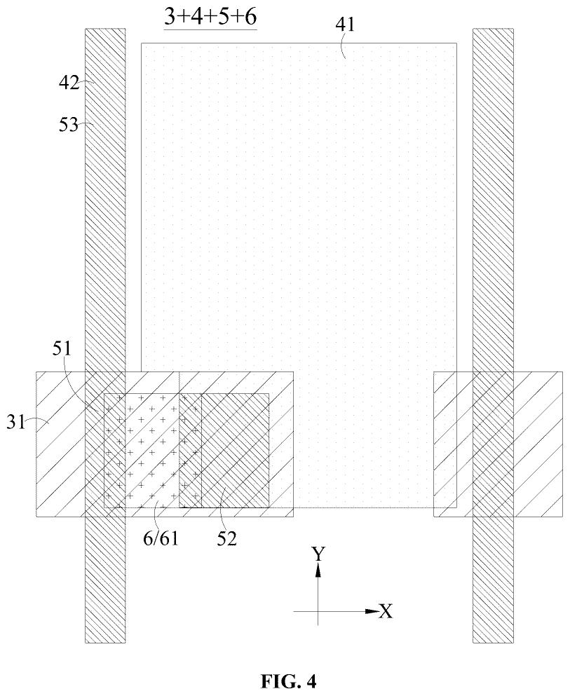

In this example embodiment, referring to FIG. 1 and FIG. 4, an organic planarization layer 6 may be provided on the side of the first conductive layer 5 away from the base substrate 1. Specifically, the material of the organic planarization layer 6 needs to be resistant to chemical solvents to protect the first conductive layer 4. It also has high light transmittance to avoid affecting the light transmittance of the display panel. It also has low polarity. Low polarity means that the dipole in the molecule is small and the charge distribution is relatively uniform. In simple terms, it is relatively symmetrical and generally has few lone pairs of electrons. Low polarity can reduce the induced charge to cause polarization, thereby reducing the back channel effect and reducing leakage current. For example, the material of the organic planarization layer 6 may be SU-8 series epoxy photoresist, and other materials with low dielectric constants may also be selected.

The organic planarization layer 6 may include a plurality of organic planarization portions 61 arranged at intervals, that is, the organic planarization portions 61 are arranged as an island structure, and one thin film transistor may include one organic planarization portion 61.

The organic planarization portion 61 is at least arranged in the first gap 54, and the organic planarization portion 61 at least does not cover the ends of the source electrode 51 and the drain electrode 52 away from the first gap 54; such an arrangement enables the source electrode 51 and the drain electrode 52 to ensure connection with the organic active layer 7 even when the area is small, so that the area of the subsequently formed organic active layer 7 is smaller, the area of the thin film transistor is smaller, and the aperture ratio of the entire array substrate and the display panel is increased.

The orthographic projection of the organic active layer 7 on the base substrate 1 is located within the orthographic projection of the light shielding layer 3 on the base substrate 1, so that the light shielding layer 3 can play a role in shielding light from reaching the organic active layer 7. Specifically, the orthographic projection of the organic active layer 7 on the base substrate 1 can overlap with the orthographic projection of the light shielding layer 3 on the base substrate 1, or the orthographic projection of the light shielding layer 3 on the base substrate 1 covers the orthographic projection of the organic active layer 7 on the base substrate 1, and the orthographic projection area of the light shielding layer 3 on the base substrate 1 is larger than the orthographic projection area of the organic active layer 7 on the base substrate 1. For example, the distance between the edge line of the orthographic projection of the light shielding layer 3 on the base substrate 1 and the edge line of the orthographic projection of the organic active layer 7 on the base substrate 1 is greater than or equal to 2 micrometers. Such an arrangement ensures that the orthographic projection of the organic active layer 7 on the base substrate 1 can be located within the orthographic projection of the light shielding layer 3 on the base substrate 1 even when an error exists in the process or equipment.

For example, as shown in FIG. 10, the organic planarization portion 61 is only arranged in the first gap 54, so that the distance between the surface of the organic planarization portion 61 away from the base substrate 1 and the base substrate 1 is equal to the distance between the surface of the first conductive layer 5 away from the base substrate 1 and the base substrate 1, that is, the organic planarization portion 61 fills the first gap 54 between the source 51 and the drain 52, and the organic planarization portion 61 covers the sharp corners at the corner parts of the source 51 and the drain 52; so that the subsequently formed organic active layer 7 does not need to climb, and no gap will be formed at the organic active layer 7, and the organic active layer 7 will not be broken due to the gaps.

As shown in FIG. 11, the organic planarization portion 61 is not only arranged in the first gap 54, but also protrudes from the first conductive layer 5, so that the distance between the surface of the organic planarization portion 61 away from the base substrate 1 and the base substrate 1 is greater than the distance between the surface of the first conductive layer 5 away from the base substrate 1 and the base substrate 1. However, the organic planarization portion 61 does not cover the first conductive layer 5. In this way, the organic planarization portion 61 fills the first gap 54 between the source 51 and the drain 52, and the organic planarization portion 61 covers the sharp corners at the corner parts of the source 51 and the drain 52; so that the subsequently formed organic active layer 7 does not need to climb the side walls of the source 51 and the drain 52, thereby avoiding the appearance of gaps in the organic active layer 7, and the organic active layer 7 will not break due to the gap.

Moreover, the distance H1 between the surface of the organic planarization portion 61 away from the base substrate 1 and the first conductive layer 5 is less than the thickness H2 of the first conductive layer 5 in the third direction Z, that is, the height of the organic planarization portion 61 protruding from the first conductive layer 5 is less than the thickness of the first conductive layer 5; the third direction Z is perpendicular to the surface of the base substrate 1 close to the first electrode layer 4. The subsequently formed organic active layer 7 climbs on the side wall of the organic planarization portion 61, but the climbing height is low, so that the organic active layer 7 is prevented from having gaps and will not be broken due to the gaps.

When the organic active layer 77 is directly in contact with the first conductive layer 54, the thickness of the first conductive layer 54 needs to be set smaller to avoid the climbing height of the organic active layer 77 being too high, and the material of the first conductive layer 54 also needs to be considered to avoid the side wall formed by the first conductive layer 54 from being too steep. However, the slope of the side wall of the first conductive layer 54 is still relatively steep. For example, the angle between the side wall of the first conductive layer 54 close to the first gap 54 and the surface of the base substrate 11 close to the first conductive layer 54 is generally greater than 70 degrees, and a sharp angle structure is easily formed at the corner position of the first conductive layer 54 away from the base substrate 11; a gap will be formed on the side wall of the first conductive layer 54 by the organic active layer 77 formed subsequently, and the organic active layer 77 is easily broken due to the gap, resulting in an open circuit; and due to the existence of the sharp angle structure, the organic active layer 77 has poor coverage at the corner position of the first conductive layer 54 away from the base substrate 11, which is also easy to cause the organic active layer 77 to break, resulting in an open circuit.

Furthermore, an angle a between the side wall of the organic planarization layer 6 close to the first gap 54 and a surface of the first conductive layer 5 close to the organic planarization layer 6 is smaller than an angle β between the side wall of the first conductive layer 5 close to the first gap 54 and a surface of the first electrode layer 4 close to the first conductive layer 5; that is, the inclination angle of the side wall of the organic planarization layer 6 is smaller than the inclination angle of the side wall of the source 51 and the drain 52 of the first conductive layer 5; specifically, an angle α between the side wall of the organic planarization portion 61 close to the first gap 54 and a surface of the first conductive layer 5 away from the base substrate 1 is less than or equal to 70°, that is, although the organic planarization portion 61 has a side wall, the slope of the side wall of the organic planarization portion 61 is relatively gentle, and even if the subsequently formed organic active layer 7 climbs the side wall of the organic planarization portion 61, no gap will appear and the layer will not break due to the gap.

In addition, the material of the organic planarization portion 61 is an organic material, and the corner part of the organic planarization portion 61 is relatively smooth. The corner part of the organic planarization portion 61 can be a curved surface, that is, the surface of the organic planarization portion 61 away from the base substrate 1 is connected to the side wall through the curved surface. No sharp corner structure is formed at the corner part of the source 51 and the drain 52. Therefore, the subsequently formed organic active layer 7 has good coverage at the corner of the organic planarization portion 61, and no fracture defects will occur at the corner bend.

However, the above two structures require high process precision. Therefore, referring to FIG. 1, the organic planarization portion 61 is not only arranged in the first gap 54, but also protrudes from the first conductive layer 5, so that the distance between the surface of the organic planarization portion 61 away from the base substrate 1 and the base substrate 1 is greater than the distance between the surface of the first conductive layer 5 away from the base substrate 1 and the base substrate 1. Moreover, a part of the organic planarization portion 61 is arranged on the side of the first conductive layer 5 away from the base substrate 1, that is, a part of the organic planarization layer 6 is arranged on the side of the source electrode 51 away from the base substrate 1, and another part of the organic planarization layer 6 is arranged on the side of the drain electrode 52 away from the base substrate 1, so that the orthographic projection of the organic planarization portion 61 on the base substrate 1 overlaps with the orthographic projection of the source electrode 51 on the base substrate 1, and the orthographic projection of the organic planarization portion 61 on the base substrate 1 overlaps with the orthographic projection of the drain electrode 52 on the base substrate 1. Specifically, the width of the overlapping portion of the orthographic projection of the organic planarization portion 61 on the base substrate 1 and the orthographic projection of the source 51 on the base substrate 1 is less than 5 microns, and the width of the overlapping portion of the orthographic projection of the organic planarization portion 61 on the base substrate 1 and the orthographic projection of the drain 52 on the base substrate 1 is also less than 5 microns, so as to avoid the organic planarization portion 61 covering more of the source 51 and the drain 52, thereby preventing the subsequently formed organic active layer 7 from being unstable in connection with the source 51 and the drain 52.

In addition, in order to avoid the organic planarization portion 231 being unable to fill the first gap due to errors in the process or equipment, the width of the overlapping portion of the orthographic projection of the organic planarization portion 61 on the base substrate 1 and the orthographic projection of the source electrode 51 on the base substrate 1 is greater than or equal to 2 microns, for example, it can be 2.5 microns, 2.85 microns, 3.1 microns, 3.6 microns, 4.25 microns, 4.7 microns, etc.; similarly, the width of the overlapping portion of the orthographic projection of the organic planarization portion 61 on the base substrate 1 and the orthographic projection of the drain electrode 52 on the base substrate 1 is also greater than or equal to 2 microns, for example, it can be 2.5 microns, 2.85 microns, 3.1 microns, 3.6 microns, 4.25 microns, 4.7 microns, etc.

Of course, the above data may also be other values depending on the product and the accuracy of process equipment.

Such arrangement enables the organic planarization portion 61 to fill up the first gap 54 between the source electrode 51 and the drain electrode 52, and the organic planarization portion 61 to completely cover the sharp corners of the corner parts of the source electrode 51 and the drain electrode 52; the subsequently formed organic active layer 7 does not need to climb the side walls of the source electrode 51 and the drain electrode 52, thereby avoiding the appearance of gaps in the organic active layer 7 and preventing it from breaking due to the gaps; moreover, the requirements for process and equipment accuracy are relatively low, and even if errors occur during the preparation process and the position of the organic planarization portion 61 is shifted, the organic planarization portion 61 will fill up the first gap 54 between the source electrode 51 and the drain electrode 52, and the organic planarization portion 61 will completely cover the sharp corners of the corners of the source electrode 51 and the drain electrode 52.

Moreover, the distance H1 between the surface of the organic planarization portion 61 away from the base substrate 1 and the first conductive layer 5 may be less than the thickness H2 of the first conductive layer 5 in the third direction Z, that is, the height of the organic planarization portion 61 protruding from the first conductive layer 5 is less than the thickness of the first conductive layer 5; the third direction Z is perpendicular to the surface of the base substrate 1 close to the first electrode layer 4. The organic active layer 7 formed subsequently climbs on the side wall of the organic planarization portion 61, but the climbing height is low, avoiding the organic active layer 7 from having gaps and will not be broken due to the gaps. Of course, in some other exemplary embodiments of the present disclosure, the distance H1 between the surface of the organic planarization portion 61 away from the base substrate 1 and the first conductive layer 5 may also be equal to or greater than the thickness H2 of the first conductive layer 5 in the third direction Z.

Furthermore, an angle a between the side wall of the organic planarization layer 6 close to the first gap 54 and a surface of the first conductive layer 5 close to the organic planarization layer 6 is smaller than an angle β between the side wall of the first conductive layer 5 close to the first gap 54 and a surface of the first electrode layer 4 close to the first conductive layer 5; that is, the inclination angle of the side wall of the organic planarization layer 6 is smaller than the inclination angle of the side wall of the source 51 and the drain 52 of the first conductive layer 5; specifically, an angle α between the side wall of the organic planarization portion 61 close to the first gap 54 and a surface of the first conductive layer 5 away from the base substrate 1 is less than or equal to 70°, that is, although the organic planarization portion 61 has a side wall, the slope of the side wall of the organic planarization portion 61 is relatively gentle, and even if the subsequently formed organic active layer 7 climbs the side wall of the organic planarization portion 61, no gap will appear and the layer will not break due to the gap.

In addition, the material of the organic planarization portion 61 is an organic material, and the corner part of the organic planarization portion 61 is relatively smooth. The corner part of the organic planarization portion 61 can be a curved surface, that is, the surface of the organic planarization portion 61 away from the base substrate 1 can be connected to the side wall through the curved surface. The sharp corner structure of the source 51 and the drain 52 will not be formed. Therefore, the subsequently formed organic active layer 7 has good coverage of the corner part of the organic planarization portion 61, and will not produce a fracture defect at the corner bend. Of course, in some other exemplary embodiments of the present disclosure, the surface of the organic planarization portion 61 away from the base substrate 1 can also be directly connected to the side wall to form an obtuse angle.

Moreover, the angle between the side wall of the organic planarization layer 6 close to the first gap 54 and the surface of the first conductive layer 54 away from the base substrate 11 cannot be too small. If it is too small, the area of the organic planarization portion 61 will be larger, so that the area of the subsequently formed organic active layer 7 will be larger, resulting in a larger area of the entire thin film transistor, which affects the aperture ratio of the display panel. Specifically, the angle between the side wall of the organic planarization layer 6 close to the first gap 54 and the surface of the first conductive layer 54 away from the base substrate 11 is greater than or equal to 30 degrees. For example, the angle between the side wall of the organic planarization layer 6 close to the first gap 54 and the surface of the first conductive layer 54 away from the base substrate 11 can be 32 degrees, 36 degrees, 42.5 degrees, 46.8 degrees, 51 degrees, 54.7 degrees, 58.4 degrees, 62 degrees, 65.3 degrees, 67.5 degrees, etc.

The thickness of the organic planarization layer 6 is greater than or equal to 300 nanometers and less than or equal to 800 nanometers. For example, the thickness of the organic planarization layer 6 can be 326 nanometers, 375 nanometers, 430 nanometers, 480 nanometers, 517 nanometers, 589 nanometers, 625 nanometers, 673 nanometers, 741 nanometers, 789 nanometers, etc.

In this exemplary embodiment, as shown in FIG. 1, an organic active layer 7 may be provided on the side of the organic planarization layer 6 away from the base substrate 1, and the organic active layer 7 is connected to the source electrode 51 and the drain electrode 52 on the side of the organic planarization portion 61 away from the first gap 54. The material of the organic active layer 7 may be an organic semiconductor (OSC) material.

Due to the planarization and protection of the organic planarization layer 6, the material selection space of the first conductive layer 5 is larger, so that the flexible array substrate can be mass-produced; and, since the organic semiconductor (OSC) material of the organic active layer 7 is a P-type material, the first conductive layer 5 needs to form an ohmic contact with the organic active layer 7, and the first conductive layer 5 needs to select a material with a larger work function, for example, the work function of the material of the first conductive layer 5 needs to be greater than 4.5 eV; therefore, considering the work function, the material of the first conductive layer 5 can be Ag+SAM, whose work function is about 5.86 eV, and Ag is closer to the base substrate 1; it can be ITO (Indium Tin Oxide), whose work function is greater than or equal to 4.57 and less than or equal to 4.93 eV; it can be Mo+surface oxidation (Molybdenum Oxide), whose work function is about 5.58 eV, and Mo is closer to the base substrate 1; it can be Mo alloy+surface oxidation (Molybdenum Oxide), whose work function is about 5.5 eV, and Mo alloy is closer to the base substrate 1; it can also be TiN, whose work function is greater than or equal to 4.49 and less than or equal to 5.29 eV; it can also be Au, whose work function is about 5.2 eV; it can also be Pt, whose work function is about 5.6 eV; it can also be Pd, whose work function is about 5.12 eV, and so on.

While considering the conductive performance at the same time, the first conductive layer 5 can be in stacked manner. For example, the first conductive layer 5 can include BF (Buffer Film), LRF (Low Resistance Film), and HWF (High Work Function Film) stacked in sequence; the buffer film is closer to the base substrate 1. The buffer film may be Mo, Mo alloy, Ti, ITO, IZO (indium zinc oxide), etc. The low resistance film may be Cu, Al, Ag, etc. The high work function film may be Ag+SAM, whose work function is about 5.86 eV; ITO (indium tin oxide), whose work function is greater than or equal to 4.57 and less than or equal to 4.93 eV; Mo+surface oxidation (molybdenum oxide), whose work function is about 5.58 eV, and Mo is closer to the base substrate 1; Mo alloy+surface oxidation (molybdenum oxide), whose work function is about 5.5 eV, and Mo alloy is closer to the base substrate 1; TiN, whose work function is greater than or equal to 4.49 and less than or equal to 5.29 eV; Au, whose work function is about 5.2 eV; Pt, whose work function is about 5.6 eV; Pd, whose work function is about 5.12 eV, etc.

SAM is a self-assembled monolayer film that can form a monomolecular layer and modify the interface between the first conductive layer 4 and the organic active layer 7 to improve the work function.

In the prior art, the material of the first conductive layer 5 is a stacked structure of MoAlMo or a stacked structure of MoNd/Cu/MoNd. Since the surface is Mo or Mo alloy material, the work function is relatively small (≤4.5 eV), which does not meet the requirements. In the present invention, surface oxidation treatment is performed, and the treatment methods include annealing, plasma, etc., so that the work function is increased to greater than or equal to 4.5 eV, and the temperature of the surface oxidation treatment process is relatively low, generally not exceeding 100° C.

In this example embodiment, as shown in FIG. 1, a gate insulating layer group 8 may be provided on the side of the organic active layer 7 away from the base substrate 1, and the orthographic projection of the gate insulating layer group 8 on the base substrate 1 coincides with the orthographic projection of the organic active layer 7 on the base substrate 1, that is, the orthographic projection of the gate insulating layer group 8 on the base substrate 1 completely coincides with the orthographic projection of the organic active layer 7 on the base substrate 1, so that the gate insulating layer group 8 and the organic active layer 7 may be formed by the same patterning process, thereby reducing the process steps and lowering the cost.

As shown in FIG. 1, the gate insulating layer group 8 may include a first gate insulating layer 81 and a second gate insulating layer 82. The first gate insulating layer 81 is arranged on the side of the organic active layer 7 away from the base substrate 1. The first gate insulating layer 81 needs to be a flexible film layer with insulating properties; and it is orthogonal to the solvent for etching the organic active layer 7 and has good compatibility performance, that is, the material of the first gate insulating layer 81 will not react with the material of the organic active layer 7, thereby ensuring the channel characteristics of the organic active layer 7; for example, the material of the first gate insulating layer 81 can be a material with a low dielectric constant.

It should be noted that an orthogonal solvent refers to a solvent with a large difference in polarity. An orthogonal solvent system is a solvent system used for applying a subsequent layer, in which the previously applied layer is insoluble.

The second gate insulating layer 82 is arranged on the side of the first gate insulating layer 81 away from the base substrate 1, and the barrier performance of the second gate insulating layer 82 against the etching liquid of the gate layer 9 is stronger than barrier performance of the first gate insulating layer 81 against the etching liquid of the gate layer 9. The second gate insulating layer 82 needs to be a flexible film layer with insulation, good environmental stability, and can block water and oxygen; it can be a cross-linked material, which is a material that undergoes a cross-linking reaction. The cross-linking reaction refers to the reaction of two or more molecules (generally linear molecules) that are bonded and cross-linked to form a relatively stable molecule (bulk molecule) of a network structure. This reaction transforms linear or slightly branched macromolecules into a three-dimensional network structure, thereby improving the strength, heat resistance, wear resistance, solvent resistance and other properties; for example, the material of the second gate insulating layer 82 can be a cross-linkable dielectric material, which can improve electrical durability.

As shown in FIG. 1, FIG. 5 and FIG. 6, a gate layer 9 may be provided on the side of the gate insulating layer group 8 away from the base substrate 1, and the gate layer 9 may include a gate 91, and the orthographic projection of the gate layer 9 on the base substrate 1 coincides with the orthographic projection of the organic active layer 7 on the base substrate 1, that is, the orthographic projection of the gate layer 9 on the base substrate 1 completely coincides with the orthographic projection of the organic active layer 7 on the base substrate 1, so that the gate layer 9 and the organic active layer 7 can be formed by the same patterning process, reducing the process steps and reducing the cost. The orthographic projection of the gate layer 9 on the base substrate 1 may be located within the orthographic projection of the light shielding layer 3 on the base substrate 1.

Since the gate layer 9, the gate insulating layer group 8 and the organic active layer 7 are formed by the same patterning process, but in the case where only the first gate insulating layer 81 is provided, since the barrier properties of the first gate insulating layer 81 and the organic active layer 7 are relatively poor, when etching the gate material layer 90, the etching liquid easily penetrates the first gate insulating layer 81 and the organic active layer 7 to corrode the first conductive layer 5, and in the case where the gate insulating layer group 8 includes the first gate insulating layer 81 and the second gate insulating layer 82, since the barrier properties of the second gate insulating layer 82 to the etching liquid of the gate layer 9 are stronger than the barrier properties of the first gate insulating layer 81 to the etching liquid of the gate layer 9. In the process of etching the gate material layer 90, the second gate insulating material layer 820 can protect the first conductive layer 5, prevent the etching liquid of the gate layer 9 from corroding the first conductive layer 5, ensure the electrical properties of the first conductive layer 5, and thus ensure the performance of the array substrate.

Therefore, in the process of etching to form the gate layer 9, the gate layer 9 can protect the gate insulating layer group 8 and the organic active layer 7 thereunder, so as to prevent the etching solution of the gate layer 9 from corroding the first conductive layer 5. Therefore, the material selection space of the gate layer 9 is relatively large, so that the flexible array substrate can be mass-produced; for example, the material of the gate layer 9 can be Ag, Mo, Cu, Al, Ti, ITO, a stacked structure of ITO/Ag/ITO, a stacked structure of Mo/Al/Mo, a stacked structure of Mo/Cu/Mo, a stacked structure of Ti/Al/Ti, and the like.

In this example embodiment, as shown in FIG. 1, a passivation layer 10 may be provided on the side of the gate layer 9 facing away from the base substrate 1. The passivation layer 10 needs to be a flexible film layer with insulating properties, good environmental stability, and the ability to block water and oxygen. Specifically, it may be a cross-linked material. The material of the passivation layer 10 may be the same as that of the second gate insulating layer 82.

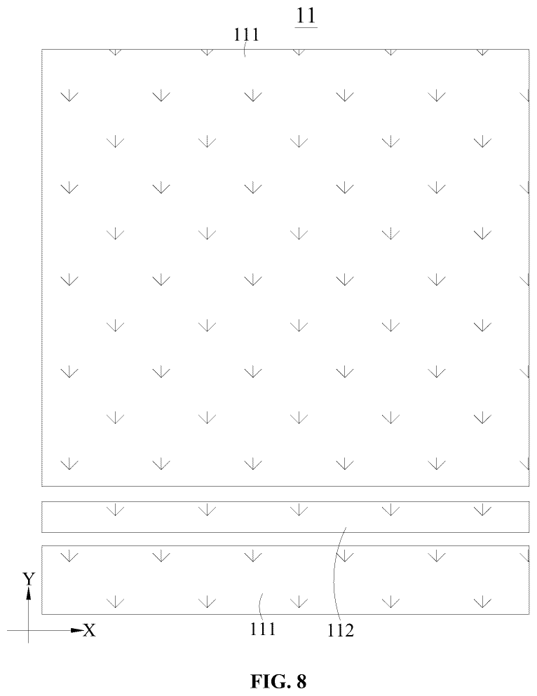

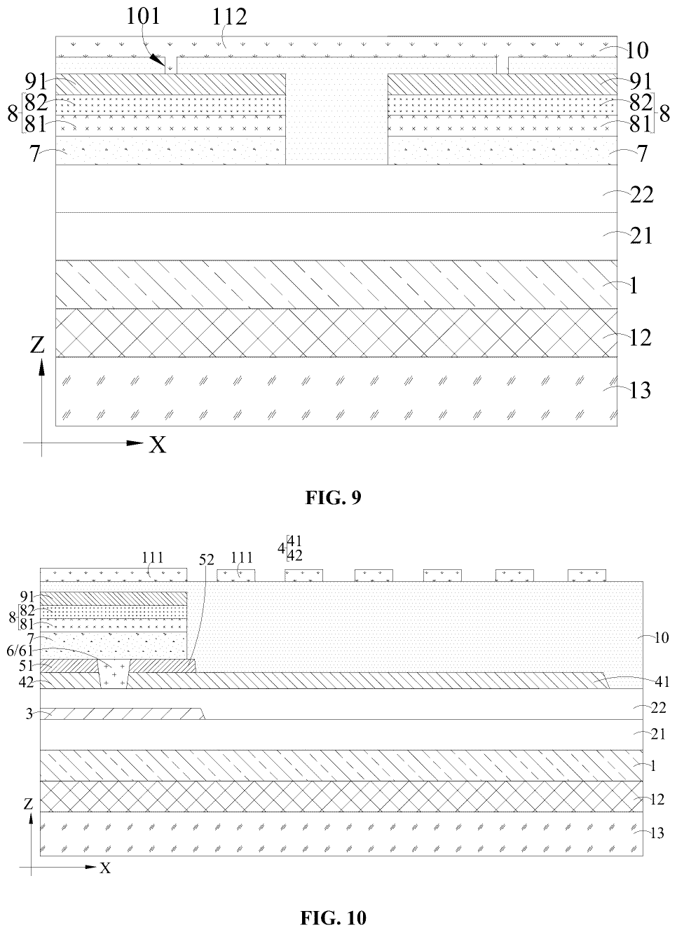

As shown in FIG. 9, a first via hole 101 is provided on the passivation layer 10, and the first via hole 101 is connected to the gate 91.

As shown in FIG. 1, FIG. 7, FIG. 8 and FIG. 9, a second electrode layer 11 may be provided on the side of the passivation layer 10 away from the base substrate 1, and the material of the second electrode layer 11 may be a transparent conductive material, for example, ITO (indium tin oxide), IZO (indium zinc oxide), etc. The second electrode layer 11 includes second electrodes 111 and gate line connecting portions 112 arranged at intervals, and the second electrode 111 may be a common electrode, so a plurality of second electrodes 111 need to be connected together, and the gate line connecting portion 112 needs to be connected to the gate 91, so the second electrode 111 and the gate line connecting portion 112 need to be arranged at intervals; the specific structure may be that the second electrode 111 may be arranged in a strip extending along the first direction X, the gate connecting portion 112 may be arranged in a strip extending along the first direction X, and the second electrode 111 and the gate connecting portion 112 may be arranged alternately in the second direction, that is, a gate connecting portion 112 is arranged between two adjacent second electrodes 111, and a second electrode 111 is arranged between two adjacent gate connecting portions 112. The plurality of second electrodes 111 may be connected in the peripheral region. Of course, the plurality of second electrodes 111 may also be bridged by other conductive film layers.

The gate connecting portion 112 serves as a gate line alone. The gate connecting portion 112 can extend along the first direction X. The gate connecting portion 112 is connected to two adjacent gates 91 through the first via hole 101 on the passivation layer 10. A plurality of gates 91 arranged along the first direction X are connected together through a plurality of gate connecting portions 112. The gate connecting portion 112 serves as a gate line to provide a scanning signal to each gate 91.

As sown in FIG. 12 and FIG. 13, in some exemplary embodiments of the present disclosure, the gate layer 9 may include not only the gate 91 but also a gate extension 92, which is connected to opposite sides of the gate 91 in the first direction X. However, since the gate extension 92, the gate 91, the gate insulating layer group 8 and the organic active layer 7 are formed by the same patterning process, in order to avoid mutual connection between the organic active layers 7 of different thin film transistors, the gate extension 92 is spaced apart from another adjacent gate 91, and the gate extension 92 extends along the first direction X, which is parallel to a surface of the base substrate 1 close to the first conductive layer 5. Of course, the gate extension 92 may be connected to a side of the gate 91 in the first direction X.

A portion of the orthographic projection of the gate extension portion 92 on the base substrate 1 may be located within the orthographic projection of the light-shielding layer 3 on the base substrate 1, and another portion of the orthographic projection of the gate extension portion 92 on the base substrate 1 may be located outside the orthographic projection of the light-shielding layer 3 on the base substrate 1, that is, the gate extension portion 92 protrudes beyond the light-shielding layer 3 in the first direction.

Since the gate layer 9 is made of metal with low resistance, such a configuration can reduce the resistance of the gate line and the power consumption of the array substrate.

In this case, a passivation layer 10 can be provided on the side of the gate layer 9 away from the base substrate 1. The passivation layer 10 needs to be a flexible film layer with insulation properties, good environmental stability, and the ability to block water and oxygen. Specifically, it can be a cross-linked material; the material of the passivation layer 10 can be the same as that of the second gate insulating layer 82.

As shown in FIG. 9, a first via hole 101 is provided on the passivation layer 10, and the first via hole 101 is connected to the gate extension portion 92.

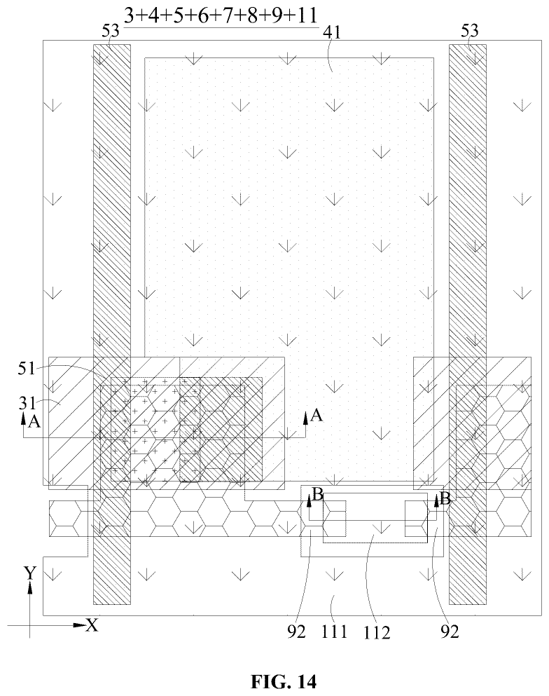

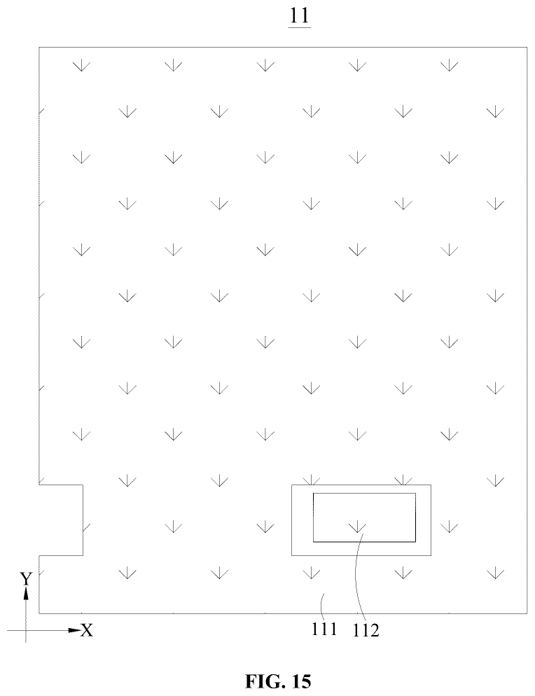

As shown in FIG. 1, FIG. 14, FIG. 15 and FIG. 9, a second electrode layer 11 may be provided on the side of the passivation layer 10 away from the base substrate 1, and the material of the second electrode layer 11 may be a transparent conductive material, for example, ITO (indium tin oxide), IZO (indium zinc oxide), etc. The second electrode layer 11 includes a second electrode 111 and a gate connecting portion 112 arranged at intervals, and the second electrode 111 may be a common electrode, so a plurality of second electrodes 111 need to be connected together, and the gate connecting portion 112 needs to be connected to the gate extension portion 92, so the second electrode 111 and the gate connecting portion 112 need to be arranged at intervals; the specific structure may be that a plurality of openings are provided on the second electrode layer 11 to form the second electrode layer 11, and a gate connecting portion 112 is provided in the opening.

The gate connecting portion 112 and the gate extension portion 92 together serve as a gate line. The gate connecting portion 112 can extend along the first direction X. The gate connecting portion 112 is connected to two adjacent gate extension portions 92 through the first via hole 101 on the passivation layer 10, that is, the gate connecting portion 112 and the gate extension portion 92 are connected to form a gate line to connect multiple gates 91 arranged along the first direction X and provide scanning signals for each gate 91.

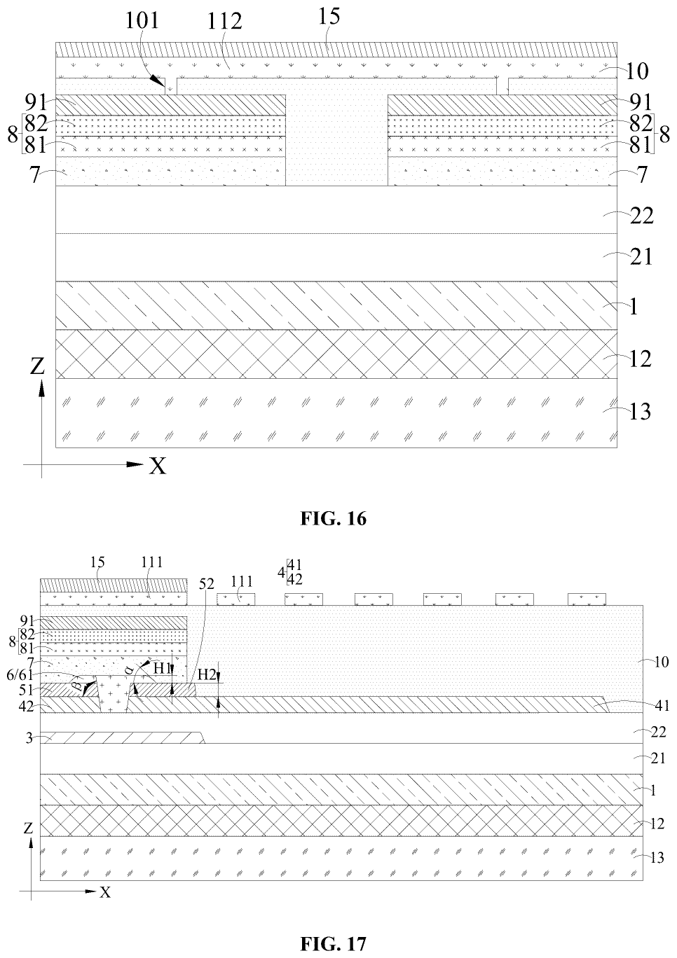

Further, as shown in FIG. 16, the array substrate may further include a conductive enhancement layer 15, which is disposed on the side of the second electrode layer 11 away from the base substrate 1, and the orthographic projection of the conductive enhancement layer 15 on the base substrate 1 coincides with the orthographic projection of the gate connecting portion 112 on the base substrate 1, that is, the conductive enhancement layer 15 is not disposed on the side of the second electrode 111 away from the base substrate 1, so as to ensure the light transmission area of the array substrate, that is, to ensure the aperture ratio of the array substrate. The conductive enhancement layer 15 is made of metal with low resistance. The conductive enhancement layer 15 can reduce the resistance of the gate connecting portion 112, thereby reducing the resistance of the gate line of the array substrate, reducing power consumption, and ensuring the uniformity of the electric field of the second electrode 111 of the array substrate. Of course, in some other exemplary embodiments of the present disclosure, as shown in FIG. 17, the conductive enhancement layer 15 can also be disposed on the side of the second electrode 111 away from the base substrate 1, but the conductive enhancement layer 15 is only disposed in the area of the second electrode 111 outside the display area, for example, the conductive enhancement layer 15 can be disposed in the portion where the second electrode 111 overlaps with the data line 53.

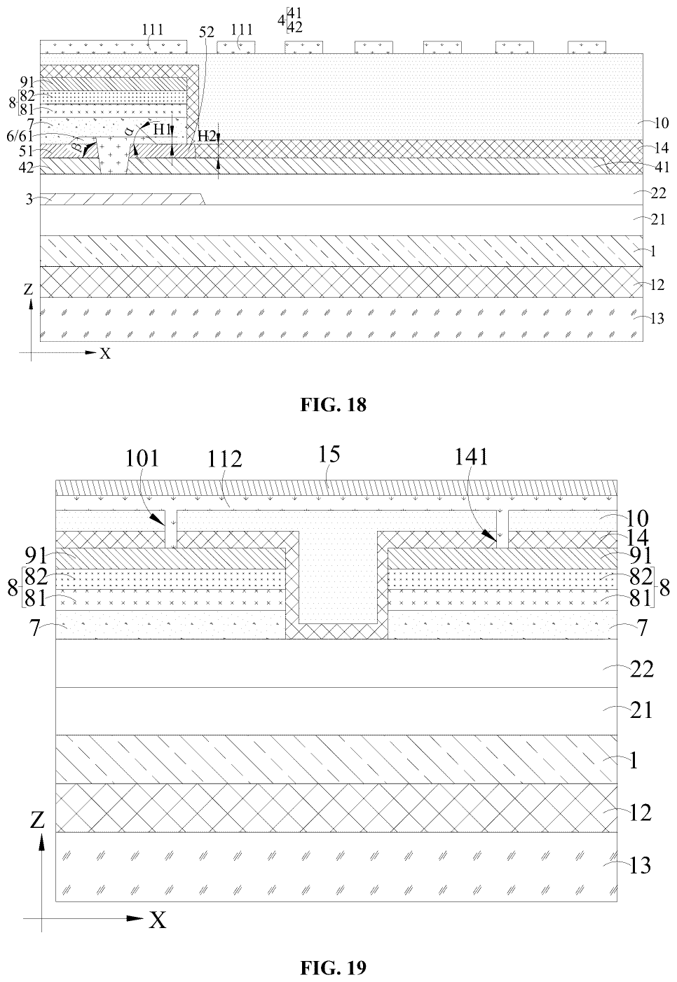

Further, as shown in FIG. 18, the array substrate may further include a protective layer 14, wherein the protective layer 14 at least covers the side wall of the organic active layer 7, and the protective layer 14 may protect the organic active layer 7.

In this exemplary embodiment, the protective layer 14 is disposed between the gate layer 9 and the passivation layer 10 and between the organic planarization layer 6 and the passivation layer 10, and covers the sidewalls of the gate 91, the organic active layer 7, and the gate insulating layer group 8. That is, the protective layer 14 is formed after the gate layer 9 is formed.

The thickness of the protective layer 14 is greater than or equal to 1000 angstroms and less than or equal to 3000 angstroms. For example, the thickness of the protective layer 14 can be 1030 angstroms, 1085 angstroms, 1162 angstroms, 1238 angstroms, 1348 angstroms, 1586 angstroms, 1651 angstroms, 1752 angstroms, 1830 angstroms, 1985 angstroms, 2162 angstroms, 2338 angstroms, 2481 angstroms, 2568 angstroms, 2615 angstroms, 2725 angstroms, 2856 angstroms, 2965 angstroms, etc.

The material of the protective layer 14 may be the same as the material of the first insulating layer 81 or the material of the first planarization layer 21. The specific requirements of the material of the first insulating layer 81 and the material of the first planarization layer 21 have been described in detail above, and therefore will not be repeated here.

The compatibility of the protective layer 14 and the organic active layer 7 is stronger than the compatibility of the passivation layer 10 and the organic active layer 7. The protective layer 14 can prevent the organic active layer 7 from contacting the passivation layer 10. Since the material compatibility between the organic active layer 7 and the passivation layer 10 is poor, for example, the organic active layer 7 and the passivation layer 10 will react, and additional by-products will be produced during the film formation process, or the organic active layer 7 and the passivation layer 10 will be mutually dissolved, resulting in damage to the organic active layer 7 and the passivation layer 10. However, the material compatibility between the protective layer 14 and the organic active layer 7 is better, that is, the material of the protective layer 14 is orthogonal to the material solvent of the organic active layer 7, that is, the material of the protective layer 14 and the material of the organic active layer 7 do not react with each other, so that the protective layer 14 and the organic active layer 7 can maintain integrity, and improve the stability of the thin film transistor, and ensure the performance of the array substrate.

In this case, as shown in FIG. 19, the gate connecting portion 112 can be connected to the gate 91 through the first via hole 101 on the passivation layer 10 and the fourth via hole 141 on the protective layer 14, and the first via hole 101 on the passivation layer 10 and the fourth via hole 141 on the protective layer 14 can be formed by the same composition process.

As shown in FIG. 20, in some other example embodiments of the present disclosure, the light-shielding layer 3 may be configured as a strip extending along the first direction X, and one light-shielding layer 3 may correspond to a plurality of thin-film transistors arranged along the first direction X, that is, the orthographic projections of the plurality of organic active layers 7 arranged along the first direction X on the base substrate 1 are located within the orthographic projections of the light-shielding layer 3 on the base substrate 1.

In this case, a passivation layer 10 can be provided on the side of the gate layer 9 away from the base substrate 1. The passivation layer 10 needs to be a flexible film layer with insulation properties, good environmental stability, and the ability to block water and oxygen. Specifically, it can be a cross-linked material; the material of the passivation layer 10 can be the same as that of the second gate insulating layer 82.

A first via hole 101 and a second via hole 102 are provided on the passivation layer 10, and the first via hole 101 is connected to the gate 91. A third via hole 221 is provided on the second planarization layer 22, and the second via hole 102 is connected to the third via hole 221 and connected to the light shielding layer 3.

A second electrode layer 11 may be provided on the side of the passivation layer 10 away from the base substrate 1. The material of the second electrode layer 11 may be a transparent conductive material, for example, ITO (indium tin oxide), IZO (indium zinc oxide), etc. The second electrode layer 11 may include a second electrode 111 and a gate connecting portion 112 arranged at intervals. The second electrode 111 may be a common electrode. The gate connecting portion 112 is arranged at intervals from the second electrode 111. The gate connecting portion 112 is connected to the gate 91 through the first via 101, and is connected to the light shielding layer 3 through the second via 102 and the third via 221. The light shielding layer 3 is multiplexed as the gate line and the second gate 91. The thin film transistor includes two gates 91, and the two gates 91 are respectively located on the upper and lower sides of the organic active layer 7 to ensure the performance of the thin film transistor.

Based on the same inventive concept, an exemplary embodiment of the present disclosure provides a method for preparing an array substrate. As shown in FIG. 21, the method for preparing the array substrate may include the following steps.

Step S10, providing a base substrate.

Step S20, forming a first electrode layer and a first conductive layer on a side of the base substrate, which are stacked in sequence, wherein the first electrode layer includes a first electrode, and the first conductive layer includes a source and a drain, a first gap is provided between the source and the drain, and an orthographic projection of the drain on the base substrate overlaps with an orthographic projection of the first electrode layer on the base substrate.

Step S30, forming an organic planarization layer, wherein the organic planarization layer includes a plurality of organic planarization portions arranged at intervals, and the organic planarization portions are arranged at least in the first gap.

Step S40, forming an organic active layer on a side of the organic planarization layer away from the base substrate, wherein the organic active layer is connected to the source and the drain on a side of the organic planarization portion away from the first gap.

In the embodiment, the organic planarization portion 61 at least does not cover the ends of the source 51 and the drain 52 away from the first gap 54, and the angle between the side wall of the organic planarization portion 61 close to the first gap 54 and the surface of the first conductive layer 5 close to the organic planarization layer 6 is smaller than the angle between the side wall of the first conductive layer 5 close to the first gap 54 and the surface of the first electrode layer 4 close to the first conductive layer 5.

The array substrate of the present disclosure can be formed by six patterning processes. Each step of the method for preparing the array substrate 100 is described in detail below.

The providing a base substrate 1 may, specifically, as shown in FIG. 22, be providing a glass substrate 13, and binding the base substrate 1 to the glass substrate 13 via an adhesive layer 12 (not shown in FIG. 22-FIG. 40). A first planarization layer 21 is formed on the side of the base substrate 1 away from the glass substrate 13.

Referring to FIG. 23, FIG. 2 and FIG. 24, a light shielding material layer is formed on the side of the first planarization layer 21 away from the base substrate 1, and the light shielding material layer is patterned to form a light shielding layer 3. The first patterning process is now completed. The specific structure of the light shielding layer 3 has been described in detail above, so it will not be repeated here.

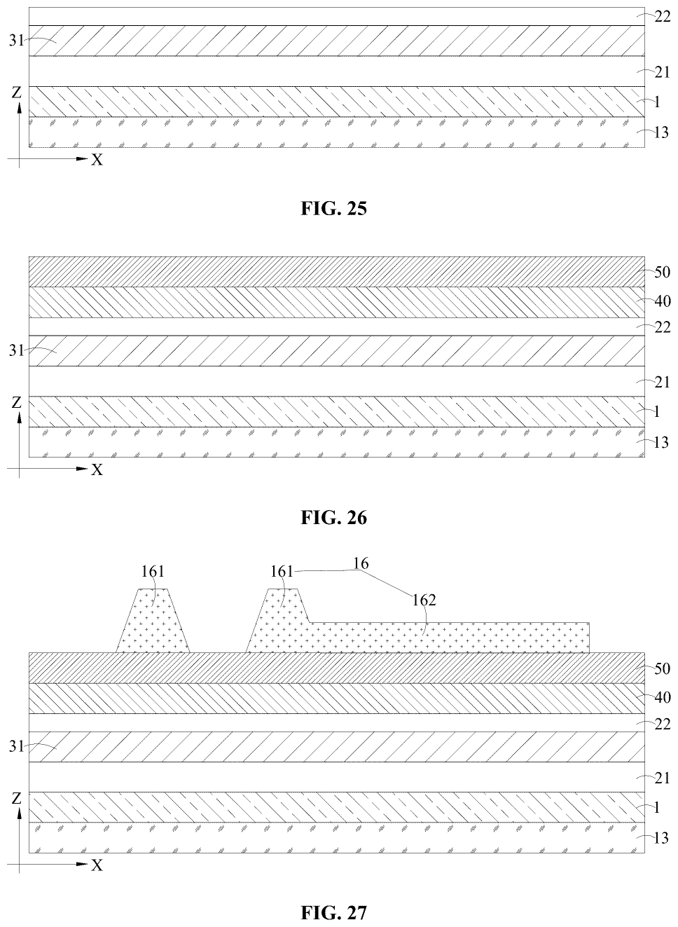

Referring to FIG. 25 and FIG. 26, a second planarization layer 22, a first electrode material layer 40 and a first conductive material layer 50 are sequentially formed on the side of the light shielding layer 3 away from the base substrate 1.

Then, the mask layer is subjected to a halftone mask process to form a mask pattern 16, specifically, a mask layer is formed on the side of the first conductive material layer 50 away from the base substrate 1, and a mask plate is placed on the side of the mask layer away from the base substrate 1, and the mask plate may include a light-transmitting portion, a light-shielding portion 31, and a semi-transmitting portion; the semi-transmitting portion is aligned to the second portion 162, that is, the orthographic projection of the semi-transmitting portion on the base substrate 1 coincides with the orthographic projection of the second portion 162 on the base substrate 1; the light-shielding portion 31 is aligned to the first portion 161, that is, the orthographic projection of the light-shielding portion 31 on the base substrate 1 coincides with the orthographic projection of the first portion 161 on the base substrate 1. The light-transmitting portion is aligned to other portions of the mask layer.

Then, referring to FIG. 27, the mask layer is exposed and developed to form a mask pattern 16, and the mask pattern 16 includes a first part 161 and a second part 162, that is, the mask layer aligned to the light-transmitting part is removed; the mask layer aligned to the semi-transmitting part is removed by a certain thickness to form the second part 162; the mask layer aligned to the light-shielding part 31 is completely retained to form the first part 161, so that the thickness of the first part 161 is greater than the thickness of the second part 162, the first part 161 is aligned to the first conductive layer 5 and a part of the first electrode layer 4, and the second part 162 is aligned to another part of the first electrode layer 4.

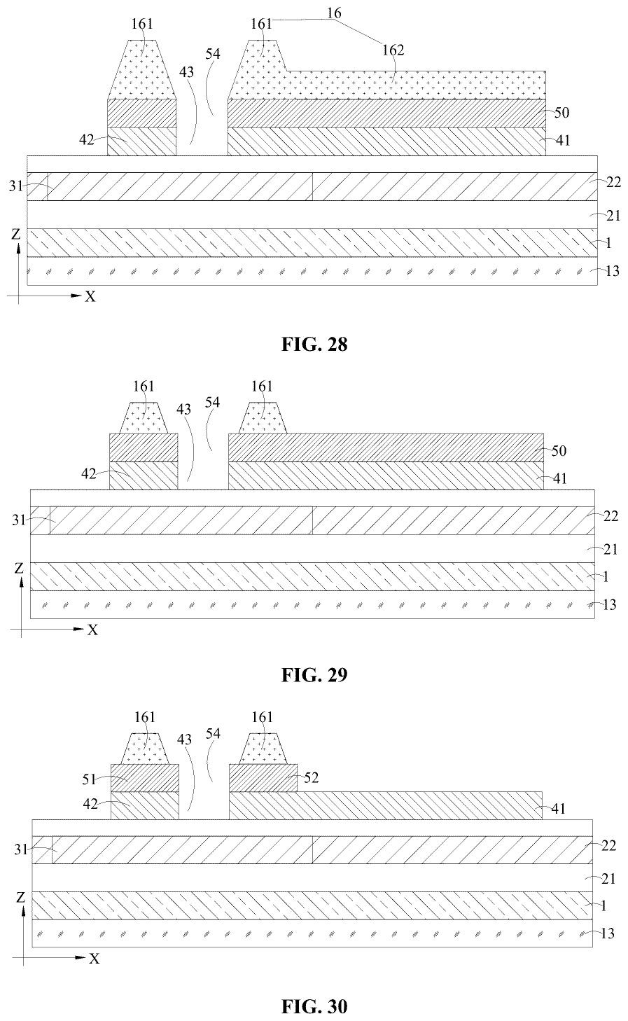

Referring to FIG. 28, the exposed first conductive material layer 50 is etched and removed for the first time, and the first electrode material layer 40 is etched and removed to form a first electrode layer 4, forming a first gap 54 between the source 51 and the drain 52 and a second gap 43 between the first electrode 41 and the resistance reduction connection portion 42; the first electrode layer 4 covered by the mask pattern 16 and the remaining first conductive material layer 50 are retained.

As shown in FIG. 29, the mask pattern 16 is ashed to remove the second portion 162, so that the first conductive material layer 50 covered by the second portion 162 is exposed; the gas used in the ashing process may include SF6 and 02. The second portion 162 is removed by the ashing process, so that the first conductive material layer 50 covered by the second portion 162 is exposed, and the thickness of the first portion 161 is also reduced.

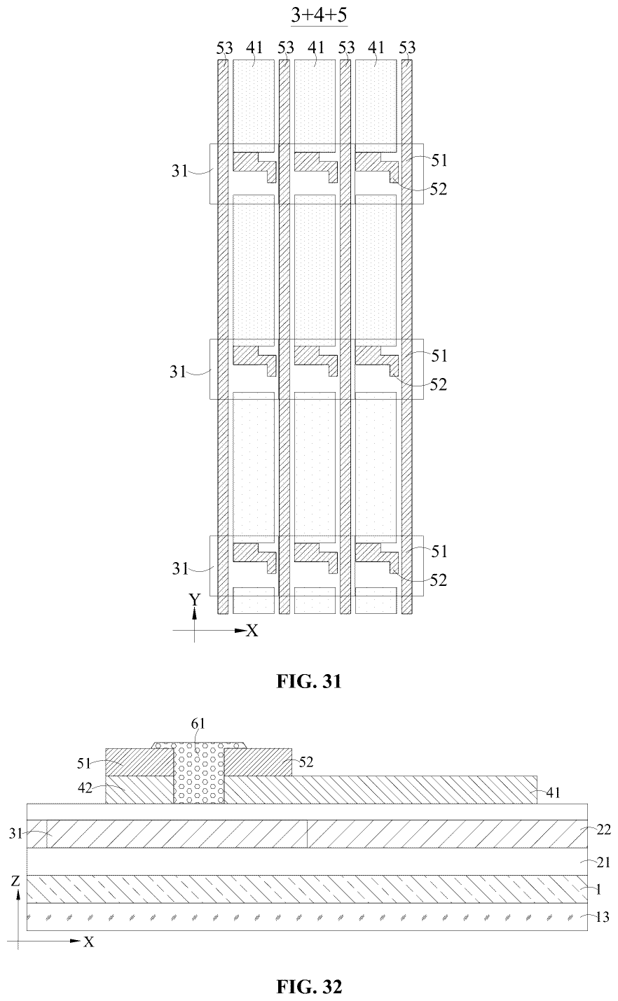

Referring to FIG. 30 and FIG. 31, the remaining first conductive material layer 50 is patterned to form the first conductive layer 5, that is, the first conductive material layer 50 covered by the second portion 162 is etched away, and the first conductive material layer 50 covered by the first portion 161 is retained to form the first conductive layer 5. Finally, the remaining first portion 161 is removed. The second patterning process is now completed.

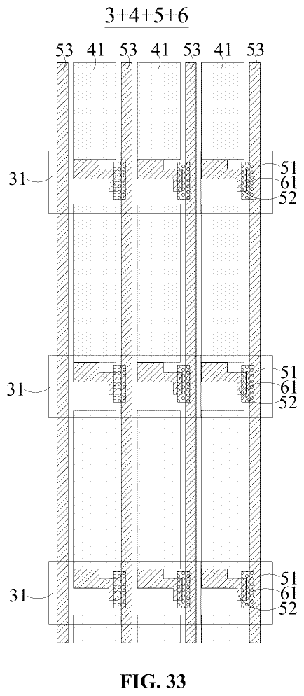

Referring to FIG. 32 and FIG. 33, an organic planarization layer 6 is formed on the side of the first conductive layer 5 away from the base substrate 1, and the organic planarization layer 6 is patterned to form a plurality of organic planarization portions 61 disposed at intervals. The third patterning process is now completed.

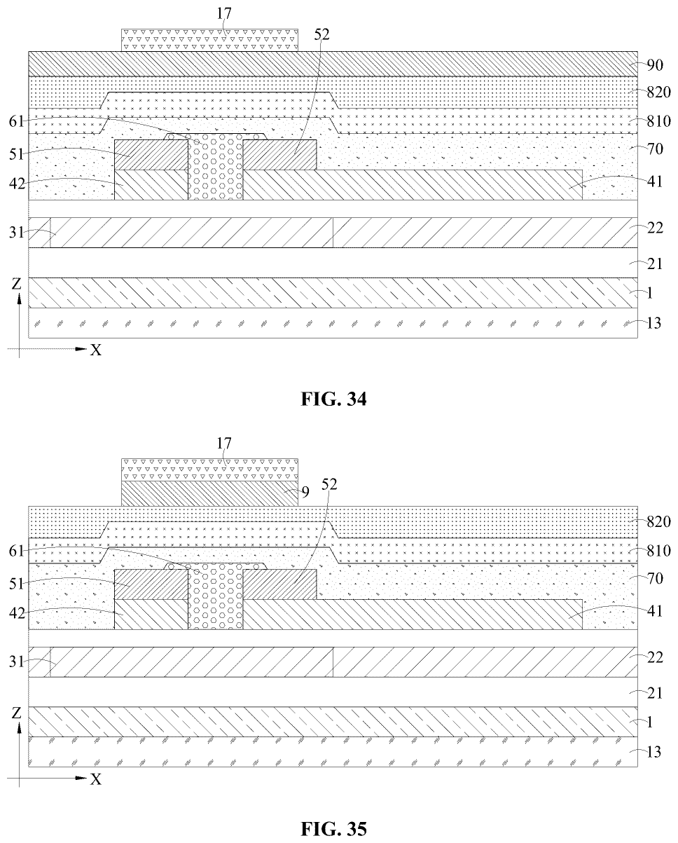

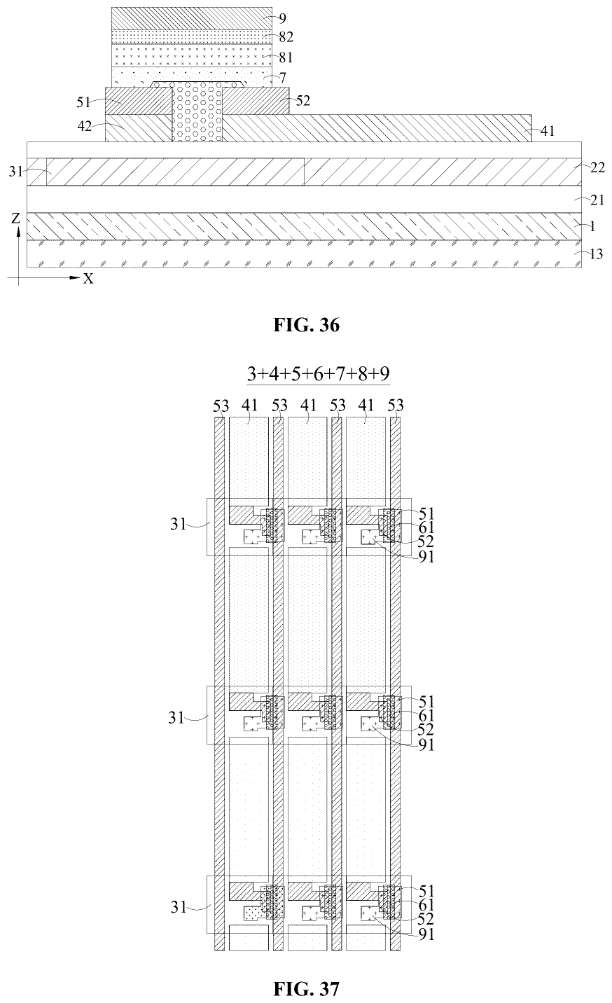

As shown in FIG. 34, an organic active material layer 70, a first gate insulating material layer 810, a second gate insulating material layer 820 and a gate material layer are sequentially formed on the side of the organic planarization portion 61 away from the base substrate 1; and a mask layer is formed on the side of the gate material layer away from the base substrate 1, and the mask layer is exposed and developed to form a second mask pattern 17. As shown in FIG. 35, the gate material layer is etched using the second mask pattern 17 as a mask to form a gate layer 9. As shown in FIG. 36 and FIG. 37, the second mask pattern 17 is removed, and the first gate insulating material layer 810, the second gate insulating material layer 820 and the organic active material layer 70 are etched using the gate layer 9 as a mask to form a gate insulating layer group 8 (a first gate insulating layer 81, a second gate insulating layer 82) and an organic active layer 7. Of course, the mask pattern 16 can also be removed after the gate insulating layer group 8 and the organic active layer 7 are formed. So far, the fourth patterning process is completed.

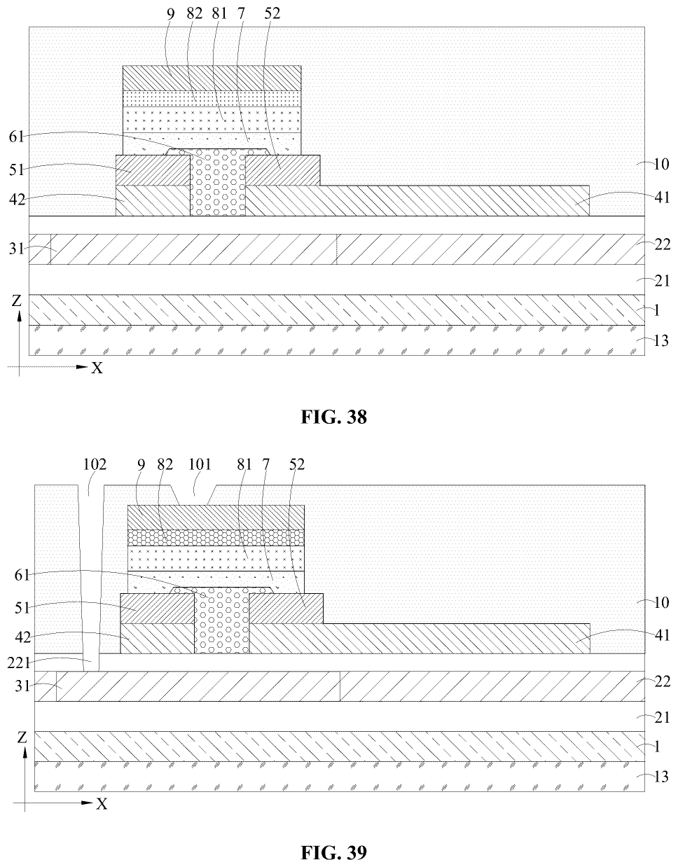

Referring to FIG. 38, a passivation layer 10 is formed on the side of the gate layer 9 facing away from the base substrate 1. Referring to FIG. 39, the passivation layer 10 is patterned to form a first via hole 101 and a second via hole 102, and a third via hole 221 is formed on the second planarization layer 22. The fifth patterning process is now completed. In addition, in some other exemplary embodiments of the present disclosure, as shown in FIG. 9, the passivation layer 10 may be patterned to form only the first via hole 101.

In some other exemplary embodiments of the present disclosure, referring to FIG. 17, when the array substrate includes a protective layer 14, the protective layer 14 and a passivation layer 10 are sequentially formed on the side of the gate layer 9 away from the base substrate 1, and the passivation layer 10 is patterned to form a first via hole 101, and the protective layer 14 is patterned to form a fourth via hole 141 at the same time, and the fourth via hole 141 is connected to the first via hole 101; or, the passivation layer 10 is patterned to form a first via hole 101 and a second via hole 102, and a third via hole 221 is formed on the second planarization layer 22, and meanwhile the protective layer 14 is patterned to form a fourth via hole 141 and a fifth via hole, and the fourth via hole 141 is connected to the first via hole 101, and the fifth via hole is connected to the second via hole 102 and the third via hole 221. The fifth patterning process is thus completed.

Referring to FIG. 20 and FIG. 40, a second electrode material layer is formed on the side of the passivation layer 10 away from the base substrate 1, and the second electrode material layer is patterned to form a second electrode layer 11 and a gate connecting portion 112. The sixth patterning process is now completed.

In some other exemplary embodiments of the present disclosure, referring to FIGS. 16 and 17, when the array substrate includes a conductive enhancement layer 15, the second electrode material layer and the conductive enhancement material layer are sequentially formed on the side of the passivation layer 10 away from the base substrate 1, and the conductive enhancement material layer is patterned to form the conductive enhancement layer 15, and the second electrode material layer is patterned to form the second electrode layer 11 and the gate connecting portion 112. Since the conductive enhancement layer 15 and the second electrode layer 11 are formed in different areas, the formation process of the second electrode layer 11 and the conductive enhancement layer 15 is the same as the formation process of the gate layer 9 and the organic active layer 7, that is, the mask layer is first subjected to a halftone mask process and then subjected to an ashing process, and the specific steps are not repeated here. The sixth patterning process is now completed.

It should be noted that, although the steps of the method for preparing an array substrate in the present disclosure are described in a specific order in the drawings, this does not require or imply that the steps must be performed in this specific order, or that all the steps shown must be performed to achieve the desired result. Additionally or alternatively, some steps may be omitted, multiple steps may be combined into one step, and/or one step may be decomposed into multiple steps, etc.

Based on the same inventive concept, an example embodiment of the present disclosure provides a display panel, which is a liquid crystal display panel. The display panel may include an array substrate, a color filter substrate and a liquid crystal layer; the array substrate may be any one of the array substrates described above, and the specific structure of the array substrate has been described in detail above, so it will not be repeated here; the color filter substrate is arranged opposite to the array substrate; the liquid crystal layer is arranged between the array substrate and the color filter substrate.

The color filter substrate may be a flexible color filter substrate, which may include a flexible substrate, a shading portion 31 and a filter portion provided on a side of the flexible substrate, and the filter portion may include a red filter portion, a green filter portion, a blue filter portion, and the like.

Based on the same inventive concept, an exemplary embodiment of the present disclosure provides a display device, which may be a roll-up display device, a foldable display device or a curved display device. The display device may include a display panel described in any one of the above. The specific structure of the display panel has been described in detail above, so it will not be repeated here.

The specific type of the display device is not particularly limited, and any type of display device commonly used in the field can be used, such as mobile devices such as mobile phones, wearable devices such as watches, VR devices, etc. Technical personnel in this field can make corresponding choices based on the specific purpose of the display device, which will not be repeated here.

It should be noted that, in addition to the display panel, the display device also includes other necessary components and components, such as a housing, a circuit board, a power cord, etc. Those skilled in the art may make corresponding supplements according to the specific use requirements of the display device, which will not be repeated here.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only.

1. An array substrate, comprising:
a base substrate;
a first electrode layer, disposed on a side of the base substrate, the first electrode layer comprising a first electrode;
a first conductive layer is, disposed on a side of the first electrode layer away from the base substrate, wherein the first conductive layer comprises a source electrode and a drain electrode, a first gap is provided between the source electrode and the drain electrode, and an orthographic projection of the drain electrode on the base substrate is overlapped with an orthographic projection of the first electrode layer on the base substrate;
an organic planarization layer, comprising a plurality of organic planarization portions arranged at intervals, wherein one organic planarization portion is arranged at least in the first gap, at least ends of the source electrode and the drain electrode away from the first gap are not covered by the organic planarization portion, and an angle between a side wall of the organic planarization portion close to the first gap and a surface of the first conductive layer close to the organic planarization layer is smaller than an angle between a side wall of the first conductive layer close to the first gap and a surface of the first electrode layer close to the first conductive layer; and
an organic active layer, disposed on a side of the organic planarization layer away from the base substrate, and the organic active layer is connected to the source electrode and the drain electrode on a side of the organic planarization portion away from the first gap.

2. The array substrate according to claim 1, wherein a distance between a surface of the organic planarization portion away from the base substrate and the base substrate is greater than or equal to a distance between a surface of the first conductive layer away from the base substrate and the base substrate.

3. The array substrate according to claim 2, wherein a portion of the organic planarization portion is arranged on the side of the first conductive layer away from the base substrate, and at a position close to the first gap, an orthographic projection of the organic planarization portion on the base substrate is overlapped with an orthographic projection of the source electrode on the base substrate, and the orthographic projection of the organic planarization portion on the base substrate is overlapped with the orthographic projection of the drain electrode on the base substrate.

4. The array substrate according to claim 1, wherein the angle between the side wall of the organic planarization portion close to the first gap and the surface of the first conductive layer close to the organic planarization layer is less than or equal to 70°.

5. The array substrate according to claim 1, wherein a distance between a surface of the organic planarization portion away from the base substrate and the first conductive layer is smaller than a thickness of the first conductive layer in a third direction, wherein the third direction is perpendicular to a surface of the base substrate close to the first electrode layer.

6. The array substrate according to claim 1, wherein a surface of the organic planarization portion away from the base substrate is connected to a side wall of the organic planarization portion via a curved surface.

7. The array substrate according to claim 1, wherein the first conductive layer further comprises a data line connected to the source electrode, and the first electrode layer further comprises:
a resistance-reducing connection portion spaced apart from the first electrode, wherein orthographic projections of the source electrode and the data line on the base substrate are located within an orthographic projection of the resistance-reducing connection portion on the base substrate.

8. The array substrate according to claim 1, wherein the array substrate further comprises:
a gate insulating layer group, disposed on a side of the organic active layer away from the base substrate, and an orthographic projection of the gate insulating layer group on the base substrate is coincided with an orthographic projection of the organic active layer on the base substrate; and
a gate layer, disposed on a side of the gate insulating layer group away from the base substrate, wherein the gate layer comprises a gate, and an orthographic projection of the gate on the base substrate is coincided with the orthographic projection of the organic active layer on the base substrate.

9. The array substrate according to claim 8, wherein the gate insulating layer group comprises:
a first gate insulating layer, disposed on the side of the organic active layer away from the base substrate; and
a second gate insulating layer, disposed on a side of the first gate insulating layer away from the base substrate, and the second gate insulating layer has a stronger barrier performance to an etching liquid of the gate layer than the first gate insulating layer.

10. The array substrate according to claim 8, wherein the array substrate further comprises:
a passivation layer, disposed on a side of the gate layer away from the base substrate;
a second electrode layer, disposed on a side of the passivation layer away from the base substrate, wherein the second electrode layer comprises a second electrode and a gate connecting portion which are arranged at intervals, and the gate connecting portion is connected to two adjacent gates.

11. The array substrate according to claim 8, wherein the gate layer further comprises:
a gate extension portion, connected to at least a side of the gate in a first direction, and the first direction is parallel to a surface of the array substrate close to the first electrode layer.

12. The array substrate according to claim 11, wherein the array substrate further comprises:
a passivation layer, disposed on a side of the gate layer away from the base substrate; and
a second electrode layer, disposed on a side of the passivation layer away from the base substrate, wherein the second electrode layer comprises a second electrode and a gate connecting portion which are arranged at intervals, and the gate connecting portion is connected to two adjacent gate extension portions.

13. The array substrate according to claim 10 or 12, wherein the array substrate further comprises:
a conductive enhancement layer, disposed on a side of the second electrode layer away from the base substrate, and an orthographic projection of the conductive enhancement layer on the base substrate is located within an orthographic projection of the gate connecting portion on the base substrate.

14. The array substrate according to claim 8, wherein the array substrate further comprises:
a light shielding layer, disposed on a side of the base substrate, and the orthographic projection of the organic active layer on the base substrate is located within an orthographic projection of the light shielding layer on the base substrate;
a second planarization layer, disposed on a side of the light shielding layer away from the base substrate, wherein the first electrode layer is disposed on a side of the second planarization layer away from the base substrate, and a third via hole is disposed on the second planarization layer;
a passivation layer, disposed on a side of the gate layer away from the base substrate, and a first via hole and a second via hole are provided on the passivation layer, wherein the first via hole is connected to the gate, and the second via hole is connected to the third via hole and connected to the light shielding layer; and
a second electrode layer, disposed on a side of the passivation layer away from the base substrate, wherein the second electrode layer comprises a second electrode and a gate connecting portion arranged at intervals, the gate connecting portion is connected to the gate through the first via hole, and is connected to the shading layer through the second via hole and the third via hole, and the shading layer is multiplexed as a gate line and a second gate.

15. The array substrate according to claim 10, wherein the array substrate further comprises:
a protective layer, at least a side wall of the organic active layer is covered by the protective layer.

16. The array substrate according to claim 15, wherein the protective layer is disposed between the gate layer and the passivation layer, and between the first electrode and the passivation layer, and side walls of the organic active layer, the gate insulating layer group and the gate are covered by the protective layer, and wherein a compatibility of the protective layer with the organic active layer is stronger than a compatibility of the passivation layer with the organic active layer.

17. The array substrate according to claim 1, wherein a work function of the first conductive layer is greater than 4.5 eV.

18-27. (canceled)

28. A display panel, comprising:
an array substrate;
a color filter substrate, disposed opposite to the array substrate; and
a liquid crystal layer, disposed between the array substrate and the color filter substrate,
wherein the array substrate comprises:
a base substrate;
a first electrode layer, disposed on a side of the base substrate, the first electrode layer comprising a first electrode;
a first conductive layer is, disposed on a side of the first electrode layer away from the base substrate, wherein the first conductive layer comprises a source electrode and a drain electrode, a first gap is provided between the source electrode and the drain electrode, and an orthographic projection of the drain electrode on the base substrate is overlapped with an orthographic projection of the first electrode layer on the base substrate;
an organic planarization layer, comprising a plurality of organic planarization portions arranged at intervals, wherein one organic planarization portion is arranged at least in the first gap, at least ends of the source electrode and the drain electrode away from the first gap are not covered by the organic planarization portion, and an angle between a side wall of the organic planarization portion close to the first gap and a surface of the first conductive layer close to the organic planarization layer is smaller than an angle between a side wall of the first conductive layer close to the first gap and a surface of the first electrode layer close to the first conductive layer; and
an organic active layer, disposed on a side of the organic planarization layer away from the base substrate, and the organic active layer is connected to the source electrode and the drain electrode on a side of the organic planarization portion away from the first gap.

29. The display panel according to claim 28, wherein the array substrate is a flexible array substrate, and the color filter substrate is a flexible color filter substrate.

30. A display device, comprising: a display panel, wherein the display device is a roll-up display device, a foldable display device or a curved display device,
wherein the display panel comprises: an array substrate; a color filter substrate, disposed opposite to the array substrate; and a liquid crystal layer, disposed between the array substrate and the color filter substrate, and
wherein the array substrate comprises:
a base substrate;
a first electrode layer, disposed on a side of the base substrate, the first electrode layer comprising a first electrode;
a first conductive layer is, disposed on a side of the first electrode layer away from the base substrate, wherein the first conductive layer comprises a source electrode and a drain electrode, a first gap is provided between the source electrode and the drain electrode, and an orthographic projection of the drain electrode on the base substrate is overlapped with an orthographic projection of the first electrode layer on the base substrate;
an organic planarization layer, comprising a plurality of organic planarization portions arranged at intervals, wherein one organic planarization portion is arranged at least in the first gap, at least ends of the source electrode and the drain electrode away from the first gap are not covered by the organic planarization portion, and an angle between a side wall of the organic planarization portion close to the first gap and a surface of the first conductive layer close to the organic planarization layer is smaller than an angle between a side wall of the first conductive layer close to the first gap and a surface of the first electrode layer close to the first conductive layer; and
an organic active layer, disposed on a side of the organic planarization layer away from the base substrate, and the organic active layer is connected to the source electrode and the drain electrode on a side of the organic planarization portion away from the first gap.
